(19) United States
(12) Patent Application Publication
(10) Pub. No.: US 2026/0091403 A1
(43) Pub. Date: Apr. 2, 2026

(54) DEPOSITION MASK AND METHOD FOR MANUFACTURING THE SAME

(71) Applicant: Samsung Display Co., LTD., Yongin-si (KR)

(72) Inventor: Sung Woon KIM, Yongin-si (KR)

(21) Appl. No.: 19/217,341

(22) Filed: May 23, 2025

(30) Foreign Application Priority Data
Oct. 2, 2024 (KR) 10-2024-0133639

(51) Int. Cl. B05B 12/20; C23C 16/40; C23C 16/455; C23C 16/56; H10K 59/12

(52) U.S. Cl. CPC B05B 12/20; C23C 16/401; C23C 16/45595; C23C 16/56; H10K 59/12

(57) ABSTRACT

A deposition mask includes a mask substrate positioned to surround a mask opening; a coating film disposed on the mask substrate and including an inorganic material; and a mask pattern positioned in a portion overlapping the mask opening and spaced apart from the coating film with a hole pattern interposed therebetween. The mask pattern includes: a top surface; a bottom surface opposing the top surface and facing the mask opening; and a side surface connecting the top surface and the bottom surface to each other and facing the hole pattern, and a first inclination angle formed by the top surface and the side surface is smaller than a second inclination angle formed by the bottom surface and the side surface.

This application claims priority to Korean Patent Application No. 10-2024-0133639, filed on Oct. 2, 2024, and all the benefits accruing therefrom under 35 U.S.C. § 119, the content of which in its entirety is herein incorporated by reference.

### BACKGROUND

### 1. Technical Field

The present disclosure relates to a deposition mask and a method for manufacturing the same.

### 2. Description of the Related Art

As the information society develops, the demand for display devices for displaying images has increased and diversified. The display devices may be display devices such as liquid crystal displays (LCDs), field emission displays (FEDs), or light emitting displays (LEDs). The light emitting display may include an organic light emitting display including organic light emitting diode elements as light emitting elements, an inorganic light emitting display including inorganic light emitting diode elements as light emitting elements, or the like.

Recently, a need for a display device that provides a high-resolution image such as an image having a resolution of 3,000 pixels per inch (PPI) or higher has increased. To this end, an organic light emitting diode on silicon (OLEDoS), which is a small organic light emitting display device having a high resolution, has been used. The OLEDoS is a device that displays an image by disposing organic light emitting diodes (OLEDs) on a semiconductor wafer substrate including complementary metal oxide semiconductors (CMOSs).

Meanwhile, in order to manufacture a self-light emitting display device such as an organic light emitting display device, a deposition method of bringing a thin film mask into close contact with a substrate and depositing an organic material at a desired position is mainly used as a technology for depositing an organic material for each pixel. When an organic material is deposited on an organic light emitting display device having a great area, a fine metal mask (FMM), which is a thin film metal mask, has been widely used. However, such a metal mask is not suitable for high-resolution patterning.

Therefore, in order to manufacture a precise thin film mask having a high resolution, a fine silicon mask (FSM) manufactured using a semiconductor substrate such as a wafer has emerged.

### SUMMARY

Aspects of the present disclosure provide a deposition mask for manufacturing a high-resolution display device, and a method for manufacturing the same.

Aspects of the present disclosure also provide a deposition mask in which efficiency of a deposition process is improved, and a method for manufacturing the same.

Aspects of the present disclosure also provide a deposition mask in which an incomplete deposition area is minimized, and a method for manufacturing the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

In an embodiment of the disclosure, a deposition mask includes a mask substrate positioned to surround a mask opening; a coating film disposed on the mask substrate and including an inorganic material; and a mask pattern positioned in a portion overlapping the mask opening and spaced apart from the coating film with a hole pattern interposed therebetween, where the mask pattern includes: a top surface; a bottom surface opposing the top surface and facing the mask opening; and a side surface connecting the top surface and the bottom surface to each other and facing the hole pattern, and a first inclination angle formed by the top surface and the side surface is smaller than a second inclination angle formed by the bottom surface and the side surface.

In an embodiment, the first inclination angle may be an acute angle, and the second inclination angle is an obtuse angle.

In an embodiment, the second inclination angle may be greater than 90° and less than or equal to 135°.

In an embodiment, a width of the top surface of the mask pattern may be greater than a width of the bottom surface of the mask pattern.

In an embodiment, the coating film includes a first coating film positioned in contact with the mask substrate; and a second coating film positioned on the first coating film, the mask pattern may be arranged in line with an upper portion of the second coating film, and the mask pattern may be spaced apart from the second coating film with the hole pattern interposed therebetween.

In an embodiment, the mask pattern and the second coating film may include the same material, and a height of the mask pattern and a height of the second coating film may be the same as each other.

In an embodiment, the height of the mask pattern may be 0.1 micrometers (μm) to 3.0 μm.

In an embodiment, the first coating film and the second coating film may include different inorganic materials from each other.

In an embodiment, the first coating film may include silicon oxide, and the second coating film may include silicon nitride.

In an embodiment, in a direction perpendicular to a major surface of the mask substrate, the coating film may overlap the mask substrate, and the mask pattern does not overlap the mask substrate.

In an embodiment, a method for manufacturing a deposition mask, includes forming a plurality of protrusion portions on a mask substrate configured as a semiconductor wafer; forming a first coating film and a second coating film on the mask substrate; planarizing the second coating film by removing a portion of the second coating film; and forming a mask opening, a mask pattern, and a hole pattern by removing portions of the mask substrate, the first coating film, and the second coating film, and the protrusion portion protrudes more than an upper surface of the mask substrate in a direction perpendicular to a major surface of the mask substrate.

In an embodiment, in the forming of the plurality of protrusion portions, each of the plurality of protrusion portions may include a top surface protruding more than the upper surface of the mask substrate; a bottom surface opposing the top surface and positioned on the same plane as the upper surface of the mask substrate; and a side surface connecting the top surface and the bottom surface to each other, and a width of the top surface may be smaller than a width of the bottom surface.

In an embodiment, in the forming of the plurality of protrusion portions, an inclination angle formed by the bottom surface and the side surface of each of the plurality of protrusion portions may be 45° to 90°.

In an embodiment, in the forming of the plurality of protrusion portions, each of the plurality of protrusion portions may have a trapezoidal shape in a cross-sectional view.

In an embodiment, in the forming of the first coating film and the second coating film, the first coating film and the second coating film may be formed by a low pressure chemical vapor deposition (LPCVD) process, and the second coating film may include low stress nitride.

In an embodiment, in the forming of the first coating film and the second coating film, the first coating film and the second coating film may each cover the mask substrate at a uniform thickness along a shape of the protrusion portion.

In an embodiment, in the planarizing of the second coating film, a portion of the second coating film overlapping the protrusion portion may be removed by at least one of a chemical mechanical polishing (CMP) process or a photolithography process.

In an embodiment, in the forming of the mask opening, the mask pattern, and the hole pattern, the mask opening, the hole pattern, and the mask pattern may be formed by removing the portions of the mask substrate, the first coating film, and the second coating film by an etching process performed in a lower surface direction of the mask substrate.

In an embodiment, in the forming of the mask opening, the mask pattern, and the hole pattern, the mask pattern may originally be a portion of the second coating film, and is then separated apart from the second coating film with the hole pattern interposed therebetween by the etching process, and the mask pattern may have a reverse tapered shape in a cross-sectional view.

In an embodiment, in the forming of the mask opening, the mask pattern, and the hole pattern, the mask substrate may be positioned to surround the mask opening, and the mask opening may be in communication with the hole pattern.

In an embodiment, an electronic device includes a display device including a display panel formed using a deposition mask. The deposition mask includes: a mask substrate positioned to surround a mask opening; a coating film disposed on the mask substrate and including an inorganic material; and a mask pattern positioned in a portion overlapping the mask opening and spaced apart from the coating film with a hole pattern interposed therebetween, where the mask pattern includes: a top surface; a bottom surface opposing the top surface and facing the mask opening; and a side surface connecting the top surface and the bottom surface to each other and facing the hole pattern, and a first inclination angle formed by the top surface and the side surface is smaller than a second inclination angle formed by the bottom surface and the side surface.

Detailed contents of other embodiments are described in a detailed description and are illustrated in the drawings.

With a deposition mask and a method for manufacturing the same according to an embodiment of the present disclosure, a high-resolution display device may be manufactured.

With the deposition mask and the method for manufacturing the same according to an embodiment of the present disclosure, efficiency of a deposition process may be effectively improved.

With the deposition mask and the method for manufacturing the same according to an embodiment of the present disclosure, an incomplete deposition area may be effectively minimized.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is an exploded perspective view illustrating a display device according to an embodiment;

FIG. 2 is a block diagram illustrating the display device according to an embodiment;

FIG. 3 is an equivalent circuit diagram of a first sub-pixel according to an embodiment;

FIG. 4 is a plan view illustrating an example of a display panel according to an embodiment;

FIGS. 5 and 6 are plan views illustrating embodiments of a display area of FIG. 4;

FIG. 7 is a cross-sectional view illustrating an example of the display panel taken along X1-X1′ of FIG. 5;

FIG. 8 is a cross-sectional view illustrating another example of a display panel included in the display device according to an embodiment;

FIG. 9 is an exploded perspective view illustrating a head mounted display device according to an embodiment;

FIG. 10 is a perspective view illustrating an augmented reality content providing device according to an embodiment;

FIG. 11 is an exploded perspective view of the augmented reality content providing device of FIG. 10 viewed in a rear surface direction;

FIG. 12 is an exploded perspective view of the augmented reality content providing device of FIG. 10 viewed in a front surface direction;

FIG. 13 is a plan view illustrating a mother semiconductor substrate including a display cell according to an embodiment;

FIG. 14 is a plan view illustrating a deposition mask according to an embodiment;

FIG. 15 is a cross-sectional view taken along line X2-X2′ of FIG. 14;

FIG. 16 is an enlarged cross-sectional view of area A of FIG. 15;

FIG. 17 is a cross-sectional view illustrating a process of manufacturing the display panel using the deposition mask according to an embodiment;

FIG. 18 is a cross-sectional view illustrating a deposition mask according to another embodiment;

FIG. 19 is a flowchart illustrating a method for manufacturing the deposition mask according to an embodiment;

FIGS. 20 and 21 are cross-sectional views illustrating S100 of FIG. 19;

FIG. 22 is an enlarged cross-sectional view of area T of FIG. 21;

FIG. 23 is a cross-sectional view illustrating S200 of FIG. 19;

FIGS. 24 and 25 are cross-sectional views illustrating S300 of FIG. 19; and

FIGS. 26 to 28 are cross-sectional views illustrating S400 of FIG. 19.

FIG. 29 is a block diagram of an electronic device according to one embodiment of the present disclosure.

FIG. 30 is a schematic diagram of an electronic device according to various embodiments of the present disclosure

### DETAILED DESCRIPTION

Embodiments of the disclosure now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it may be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the drawing figures. It will be understood that relative terms are intended to encompass different orientations of the device in addition to the orientation depicted in the drawing figures. For example, if the device in one of the drawing figures is turned over, elements described as being on the “lower” side of other elements would then be oriented on “upper” sides of the other elements. The term “lower,” may therefore, encompasses both an orientation of “lower” and “upper,” depending on the particular orientation of the figure. Similarly, if the device in one of the drawing figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” may mean within one or more standard deviations, or within ±10%, 5%, or 2% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the drawing figures are schematic in nature and their shapes are not intended to illustrate the precise shape of a region and are not intended to limit the scope of the claims.

Throughout the disclosure, the expression “at least one of a, b or c” indicates only a, only b, only c, both a and b, both a and c, both b and c, all of a, b, and c, or variations thereof. Hereinafter, embodiments will be described in detail with reference to the accompanying drawings.

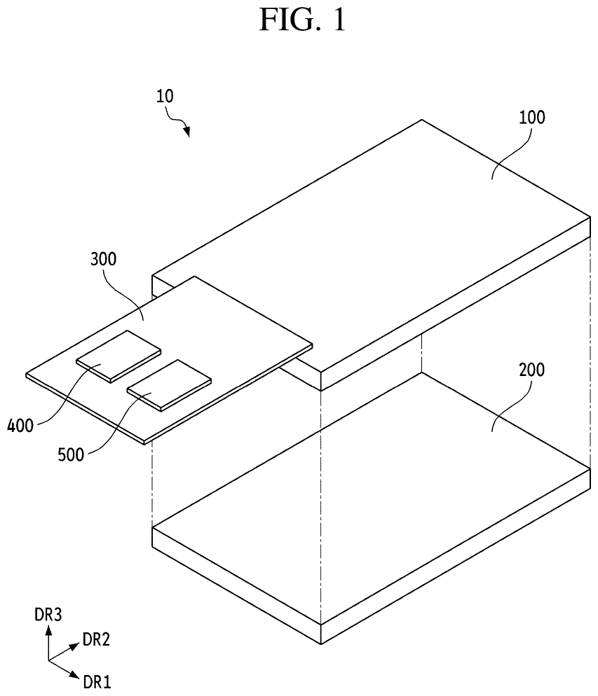

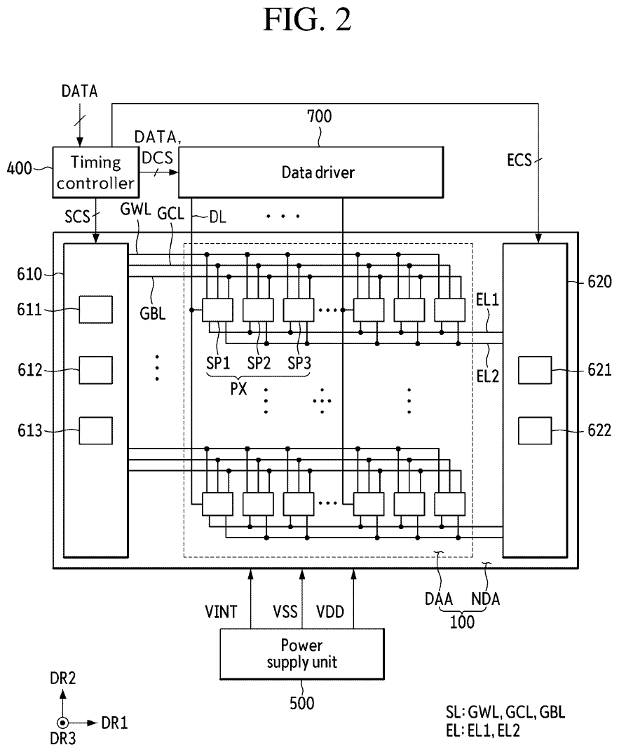

FIG. 1 is an exploded perspective view illustrating a display device according to an embodiment. FIG. 2 is a block diagram illustrating the display device according to an embodiment.

Referring to FIGS. 1 and 2, a display device 10 according to an embodiment is a device that displays a moving image or a still image. The display device 10 according to an embodiment may be applied to portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). For example, the display device 10 according to an embodiment may be applied as a display unit of televisions, laptop computers, monitors, billboards, or the Internet of Things (IOTs). Alternatively, the display device 10 according to an embodiment may be applied to smart watches, watch phones, or head mounted displays (HMDs) for implementing virtual reality and augmented reality.

The display device 10 according to an embodiment may include a display panel 100, a heat dissipation layer 200, a circuit board 300, a timing controller 400, and a power supply unit 500.

The display panel 100 may have a shape similar to a rectangular shape in a plan view. For example, the display panel 100 may have a shape similar to a rectangular shape, in a plan view, having short sides in a first direction DR1 and long sides in a second direction DR2 crossing the first direction DR1. In the display panel 100, a corner where the short side in the first direction DR1 and the long side in the second direction DR2 meet may have a round shape so as to have a predetermined curvature or a right-angled shape A shape of the display panel 100 in a plan view is not limited to the rectangular shape, and may be a shape similar to other polygonal shapes, a circular shape, or an elliptical shape in another embodiment. A shape of the display device 10 in a plan view may follow the shape of the display panel 100 in a plan view, but an embodiment of the present disclosure is not limited thereto. As used herein, the “plan view” is a view in a thickness direction (i.e., third direction DR3) of the display device 10 or a deposition mask 800.

In the drawings, the first direction DR1 and the second direction DR2 are horizontal directions, respectively, and cross each other. For example, the first direction DR1 and the second direction DR2 may be orthogonal to each other. In addition, a third direction DR3 may be a perpendicular direction crossing, for example, orthogonal to, the first direction DR1 and the second direction DR2. Unless otherwise defined, directions indicated by arrows of the first to third directions DR1, DR2, and DR3 may be referred to as one side, and directions opposite to one side may be referred to as the other side. In addition, the terms “on”, “upper side”, “upper portion”, “top, and “upper surface” as used herein refer to a direction toward which an arrow of the third direction DR3 is directed in the drawings, and the terms “below”, “lower side”, “lower portion”, “bottom, and “lower surface” used as herein refer to a direction opposite to the direction toward which the arrow of the third direction DR3 is directed in the drawings.

The display panel 100 may include a display area DAA that displays an image and a non-display area NDA that does not display an image, as illustrated in FIG. 2.

The display area DAA may include a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1 and may be disposed in the second direction DR2. The plurality of data lines DL may extend in the second direction DR2 and may be disposed in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

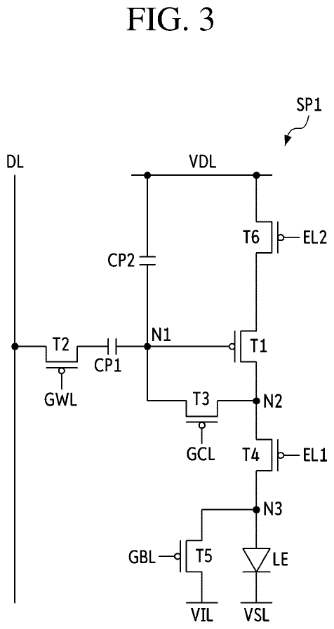

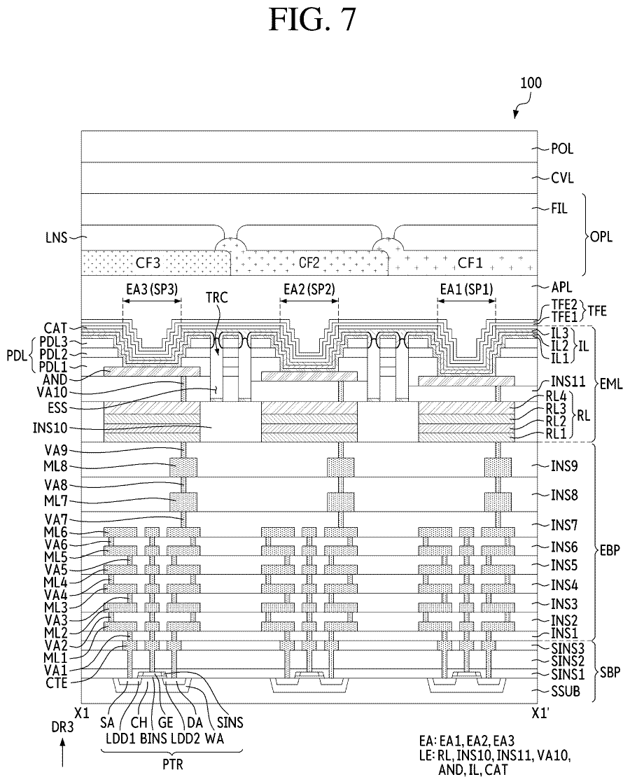

The plurality of pixels PX may include first to third sub-pixels SP1, SP2, and SP3. The first to third sub-pixels SP1, SP2, and SP3 may include a plurality of pixel transistors as illustrated in FIG. 3 to be described below, and the plurality of pixel transistors may be formed by a semiconductor process and disposed on a semiconductor substrate SSUB (see FIG. 7). For example, a plurality of pixel transistors of a data driver 700 may be configured as complementary metal oxide semiconductors (CMOSs).

Each of the first to third sub-pixels SP1, SP2, and SP3 may be connected to any one of the plurality of write scan lines GWL, any one of the plurality of control scan lines GCL, any one of the plurality of bias scan lines GBL, any one of the plurality of first emission control lines EL1, any one of the plurality of second emission control lines EL2, and any one of the plurality of data lines DL. Each of the first to third sub-pixels SP1, SP2, and SP3 may receive a data voltage of the data line DL according to a write scan signal of the write scan line GWL, and allow a light emitting element to emit light according to the data voltage.

The non-display area NDA may include a scan driver 610, an emission driver 620, and a data driver 700.

The scan driver 610 may include a plurality of scan transistors, and the emission driver 620 may include a plurality of emission transistors. The plurality of scan transistors and the plurality of emission transistors may be formed by a semiconductor process and disposed on the semiconductor substrate SSUB (see FIG. 7). For example, the plurality of scan transistors and the plurality of emission transistors may be configured as CMOSs. It has been illustrated in FIG. 2 that the scan driver 610 is disposed on the left side of the display area DAA and the emission driver 620 is disposed on the right side of the display area DAA, but the present disclosure is not limited thereto. For another example, the scan drivers 610 and the emission drivers 620 may be disposed on both the left and right sides of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing controller 400. The write scan signal output unit 611 may generate write scan signals according to the scan timing control signal SCS of the timing controller 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The emission driver 620 may include a first emission control driver 621 and a second emission control driver 622. Each of the first emission control driver 621 and the second emission control driver 622 may receive an emission timing control signal ECS from the timing controller 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include a plurality of data transistors, and the plurality of data transistors may be formed by a semiconductor process and disposed on the semiconductor substrate SSUB (see FIG. 7). For example, the plurality of data transistors may be configured as CMOSs.

The data driver 700 may receive digital video data DATA and a data timing control signal DCS from the timing controller 400. The data driver 700 may convert the digital video data DATA into analog data voltages according to the data timing control signal DCS and output the analog data voltages to the data lines DL. In this case, the sub-pixels SP1, SP2, and SP3 may be selected by the write scan signals of the scan driver 610, and the data voltages may be supplied to the selected sub-pixels SP1, SP2, and SP3.

The heat dissipation layer 200 may overlap the display panel 100 in the third direction DR3, which is a thickness direction of the display panel 100. The heat dissipation layer 200 may be disposed on one surface, for example, a rear surface, of the display panel 100. The heat dissipation layer 200 may serve to dissipate heat generated from the display panel 100. The heat dissipation layer 200 may include a layer made of graphite or metal such as silver (Ag), copper (Cu), or aluminum (Al) having high thermal conductivity.

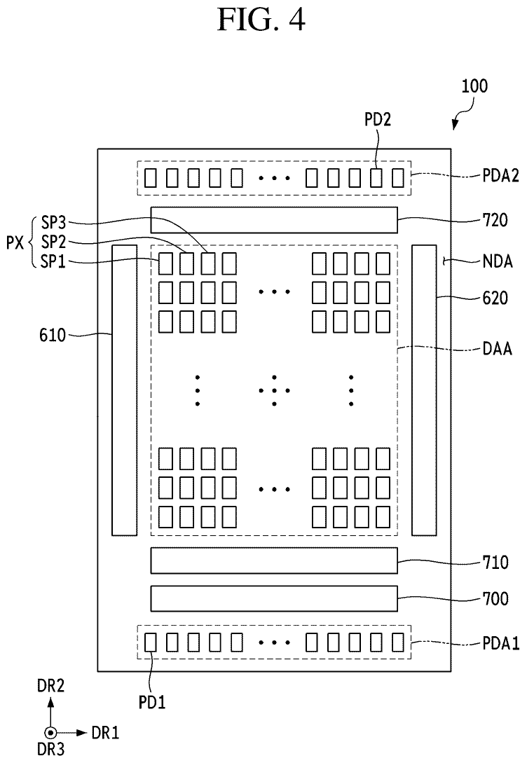

The circuit board 300 may be electrically connected to a plurality of first pads PD1 (see FIG. 4) of a first pad unit PDA1 (see FIG. 4) of the display panel 100 using a conductive adhesive member such as an anisotropic conductive film. The circuit board 300 may be a flexible printed circuit board or a flexible film having a flexible material. It has been illustrated in FIG. 1 that the circuit board 300 is unbent, but the circuit board 300 may be bent. In this case, one end of the circuit board 300 may be disposed on the rear surface of the display panel 100 and/or a rear surface of the heat dissipation layer 200. One end of the circuit board 300 may be an end opposite to the other end of the circuit board 300 connected to the plurality of first pads PD1 (see FIG. 4) of the first pad unit PDA1 (see FIG. 4) of the display panel 100 using the conductive adhesive member.

The timing controller 400 may receive digital video data and timing signals from the outside. The timing controller 400 may generate the scan timing control signal SCS, the emission timing control signal ECS, and the data timing control signal DCS for controlling the display panel 100 according to the timing signals. The timing controller 400 may output the scan timing control signal SCS to the scan driver 610 and output the emission timing control signal ECS to the emission driver 620. The timing controller 400 may output the digital video data and the data timing control signal DCS to the data driver 700.

The power supply unit 500 may generate a plurality of panel driving voltages according to an external source voltage. For example, the power supply unit 500 may generate a first driving voltage VSS, a second driving voltage VDD, and a third driving voltage VINT and supply the first driving voltage VSS, the second driving voltage VDD, and the third driving voltage VINT to the display panel 100. The first driving voltage VSS, the second driving voltage VDD, and the third driving voltage VINT will be described later with reference to FIG. 3.

Each of the timing controller 400 and the power supply unit 500 may be configured as an integrated circuit (IC) and attached to one surface of the circuit board 300. In this case, the scan timing control signal SCS, the emission timing control signal ECS, the digital video data DATA, and the data timing control signal DCS of the timing controller 400 may be supplied to the display panel 100 through the circuit board 300. In addition, the first driving voltage VSS, the second driving voltage VDD, and the third driving voltage VINT of the power supply unit 500 may be supplied to the display panel 100 through the circuit board 300.

Alternatively, each of the timing controller 400 and the power supply unit 500 may be disposed in the non-display area NDA of the display panel 100, similar to the scan driver 610, the emission driver 620, and the data driver 700. In this case, the timing controller 400 may include a plurality of timing transistors, and the power supply unit 500 may include a plurality of power transistors. The plurality of timing transistors and the plurality of power transistors may be formed by a semiconductor process and disposed on the semiconductor substrate SSUB (see FIG. 7). For example, the plurality of timing transistors and the plurality of power transistors may be configured as CMOSs. Each of the timing controller 400 and the power supply unit 500 may be disposed between the data driver 700 and the first pad unit PDA1 (see FIG. 4).

FIG. 3 is an equivalent circuit diagram of a first sub-pixel according to an embodiment.

Referring to FIG. 3 in addition to FIGS. 1 and 2, the first sub-pixel SP1 may be connected to a write scan line GWL, a control scan line GCL, a bias scan line GBL, a first emission control line EL1, a second emission control line EL2, and a data line DL. In addition, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied That is, the first driving voltage line VSL may be a low potential voltage line, the second driving voltage line VDL may be a high potential voltage line, and the third driving voltage line VIL may be an initialization voltage line. In this case, the first driving voltage VSS may be a voltage lower than the third driving voltage VINT. The second driving voltage VDD may be a voltage higher than the third driving voltage VINT.

The first sub-pixel SP1 may include a plurality of transistors T1 to T6, a light emitting element LE, a first capacitor CP1, and a second capacitor CP2.

The light emitting element LE may emit light according to a driving current (source-drain current: I_{ds}) flowing through a channel of a first transistor T1. An amount of light emitted from the light emitting element LE may be proportional to the driving current. The light emitting element LE may be disposed between a fourth transistor T4 and the first driving voltage line VSL. A first electrode of the light emitting element LE may be connected to a drain electrode of the fourth transistor T4, and a second electrode of the light emitting element LE may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but an embodiment of the present disclosure is not limited thereto. For another example, the light emitting element LE may be an inorganic light emitting element including a first electrode, a second electrode, and an inorganic semiconductor disposed between the first electrode and the second electrode, and may be, for example, a micro light emitting diode.

The first transistor T1 may be a driving transistor controlling the driving current flowing between a source electrode and a drain electrode according to a voltage applied to a gate electrode thereof. The first transistor T1 may include the gate electrode connected to a first node N1, the source electrode connected to a drain electrode of a sixth transistor T6, and the drain electrode connected to a second node N2.

A second transistor T2 may be disposed between one electrode of the first capacitor CP1 and the data line DL. The second transistor T2 may be turned on by a write scan signal of the write scan line GWL to connect one electrode of the first capacitor CP1 to the data line DL. For this reason, a data voltage of the data line DL may be applied to one electrode of the first capacitor CP1. The second transistor T2 may include a gate electrode connected to the write scan line GWL, a source electrode connected to the data line DL, and a drain electrode connected to one electrode of the first capacitor CP1.

A third transistor T3 may be disposed between the first node N1 and the second node N2. The third transistor T3 may be turned on by a control scan signal of the control scan line GCL to connect the first node N1 to the second node N2. For this reason, the gate electrode and the drain electrode of the first transistor T1 are connected to each other, and thus, the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 may be turned on by a first emission control signal of the first emission control line EL1 to connect the second node N2 to the third node N3. For this reason, the driving current of the first transistor T1 may be supplied to the light emitting element LE. The fourth transistor T4 may include a gate electrode connected to the first emission control line EL1, a source electrode connected to the second node N2, and the drain electrode connected to the third node N3.

A fifth transistor T5 may be disposed between the third node N3 and the third driving voltage line VIL. The fifth transistor T5 may be turned on by a bias scan signal of the bias scan line GBL to connect the third node N3 to the third driving voltage line VIL. For this reason, the third driving voltage VINT of the third driving voltage line VIL may be applied to the first electrode of the light emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 may be turned on by a second emission control signal of the second emission control line EL2 to connect the source electrode of the first transistor T1 to the second driving voltage line VDL. For this reason, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and the drain electrode connected to the source electrode of the first transistor T1.

The first capacitor CP1 may be disposed between the first node N1 and the drain electrode of the second transistor T2. The first capacitor CP1 may include one electrode connected to the drain electrode of the second transistor T2 and the other electrode connected to the first node N1.

The second capacitor CP2 may be disposed between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 may be a contact point between the gate electrode of the first transistor T1, the drain electrode of the third transistor T3, the other electrode of the first capacitor CP1, and one electrode of the second capacitor CP2. The second node N2 may be a contact point between the drain electrode of the first transistor T1, the source electrode of the third transistor T3, and the source electrode of the fourth transistor T4. The third node N3 may be a contact point between the drain electrode of the fourth transistor T4, the source electrode of the fifth transistor T5, and the first electrode of the light emitting element LE.

Each of the first to sixth transistors T1 to T6 may be a metal oxide semiconductor field effect transistor (MOSFET). For example, each of the first to sixth transistors T1 to T6 may be a P-type MOSFET, but an embodiment of the present disclosure is not limited thereto. Each of the first to sixth transistors T1 to T6 may be an N-type MOSFET in another embodiment. Alternatively, some of the first to sixth transistors T1 to T6 may be P-type MOSFETs, and the others of the first to sixth transistors T1 to T6 may be N-type MOSFETs.

It has been illustrated in FIG. 3 that the first sub-pixel SP1 includes six transistors T1 to T6 and two capacitors CP1 and CP2, but an equivalent circuit diagram of the first sub-pixel SP1 is not limited to that illustrated in FIG. 3. For another example, the number of transistors and the number of capacitors in the first sub-pixel SP1 may be variously modified.

In addition, an equivalent circuit diagram of the second sub-pixel SP2 and an equivalent circuit diagram of the third sub-pixel SP3 may be substantially the same as the equivalent circuit diagram of the first sub-pixel SP1 described with reference to FIG. 3. Therefore, a description of the equivalent circuit diagram of the second sub-pixel SP2 and the equivalent circuit diagram of the third sub-pixel SP3 is omitted in the present disclosure.

FIG. 4 is a plan view illustrating an example of a display panel according to an embodiment.

Referring to FIG. 4, the display area DAA of the display panel 100 according to an embodiment may include a plurality of pixels PX arranged in a matrix form. The non-display area NDA of the display panel 100 according to an embodiment may include a scan driver 610, an emission driver 620, a data driver 700, a first distribution circuit 710, a second distribution circuit 720, a first pad unit PDA1, and a second pad unit PDA2.

The scan driver 610 may be disposed on a first side of the display area DAA, and the emission driver 620 may be disposed on a second side of the display area DAA. For example, the scan driver 610 may be disposed on the other side of the display area DAA in the first direction DR1, and the emission driver 620 may be disposed on one side of the display area DAA in the first direction DR1. That is, the scan driver 610 may be disposed on the left side of the display area DAA, and the emission driver 620 may be disposed on the right side of the display area DAA. However, an embodiment of the present disclosure is not limited thereto, and the scan drivers 610 and the emission drivers 620 may be disposed on both the first and second sides of the display area DAA in another embodiment.

The first pad unit PDA1 may include a plurality of first pads PD1 connected to pads or bumps of the circuit board 300 through a conductive adhesive member. The first pad unit PDA1 may be disposed on a third side of the display area DAA. For example, the first pad unit PDA1 may be disposed on the other side of the display area DAA in the second direction DR2. That is, the first pad unit PDA1 may be disposed on the lower side of the display area DAA.

The first pad unit PDA1 may be disposed outside the data driver 700 in the second direction DR2. That is, the first pad unit PDA1 may be disposed closer to an edge of the display panel 100 than the data driver 700 is.

The second pad unit PDA2 may include a plurality of second pads PD2 corresponding to inspection pads that inspect whether or not the display panel 100 operates normally. The plurality of second pads PD2 may be connected to a jig or a probe pin or connected to a circuit board for inspection in an inspection process. The circuit board for inspection may be a printed circuit board made of a rigid material or a flexible printed circuit board made of a flexible material.

The first distribution circuit 710 may distribute data voltages applied through the first pad unit PDA1 to the plurality of data lines DL. For example, the first distribution circuit 710 may distribute data voltages applied through one first pad PD1 of the first pad unit PDA1 to P data lines DL (P is a positive integer of 2 or more), and for this reason, the number of first pads PD1 may be reduced. The first distribution circuit 710 may be disposed on the third side of the display area DAA of the display panel 100. For example, the first distribution circuit 710 may be disposed on the other side of the display area DAA in the second direction DR2. That is, the first distribution circuit 710 may be disposed on the lower side of the display area DAA.

The second distribution circuit 720 may distribute signals applied through the second pad unit PDA2 to the scan driver 610, the emission driver 620, and the data lines DL. The second pad unit PDA2 and the second distribution circuit 720 may be components for inspecting an operation of each of the pixels PX of the display area DAA. The second distribution circuit 720 may be disposed on a fourth side of the display area DAA of the display panel 100. For example, the second distribution circuit 720 may be disposed on one side of the display area DAA in the second direction DR2. That is, the second distribution circuit 720 may be disposed on the upper side of the display area DAA.

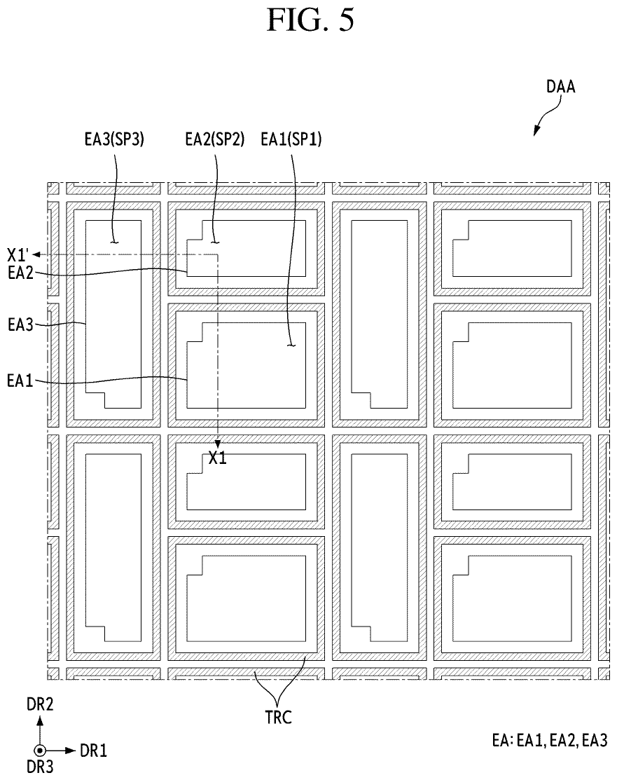

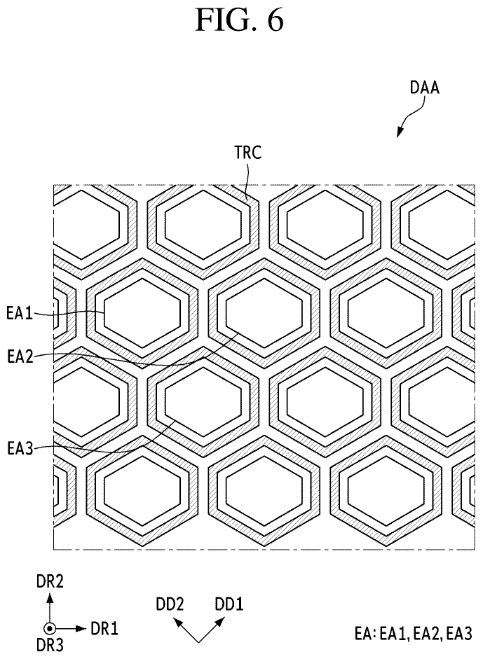

FIGS. 5 and 6 are plan views illustrating embodiments of a display area of FIG. 4.

Referring to FIGS. 5 and 6, in a portion overlapping the display area DAA, each of the plurality of pixels PX may include a first emission area EA1 that is an emission area of the first sub-pixel SP1, a second emission area EA2 that is an emission area of the second sub-pixel SP2, and a third emission area EA3 that is an emission area of the third sub-pixel SP3.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band may indicate that a main peak wavelength of the light is included in a wavelength band of approximately 370 nm to 460 nm, the green wavelength band may indicate that a main peak wavelength of the light is included in a wavelength band of approximately 480 nm to 560 nm, and the red wavelength band may indicate that a main peak wavelength of the light is included in a wavelength band of approximately 600 nm and 750 nm.

In some embodiments, emission areas EA may be disposed in a stripe structure in which they are arranged in the first direction DR1 and the second direction DR2 as illustrated in FIG. 5, a PenTile® structure having a diamond arrangement, or a hexagonal structure in which emission areas having a hexagonal shape in a plan view are arranged as illustrated in FIG. 6. However, an embodiment of the present disclosure is not limited thereto, and in another embodiment the emission areas EA may have a structure in which other polygonal, circular, elliptical, or irregular shapes in a plan view are arranged, in addition to the above-described arrangement structure.

In some embodiments, when the emission areas EA have the stripe structure, the first emission area EA1 and the second emission area EA2 may neighbor to each other in the second direction DR2, and the first emission area EA1 and the third emission area EA3, and the second emission area EA2 and the third emission area EA3 may neighbor to each other in the first direction DR1. An area of the first emission area EA1, an area of the second emission area EA2, and an area of the third emission area EA3 may be different from each other.

In some embodiments, when the emission areas EA have the hexagonal structure, the first emission area EA1 and the second emission area EA2 may neighbor to each other in the first direction DR1, but the second emission area EA2 and the third emission area EA3 may neighbor to each other in a first diagonal direction DD1, and the first emission area EA1 and the third emission area EA3 may neighbor to each other in a second diagonal direction DD2. In this case, the first diagonal direction DD1 crosses each of the first direction DR1 and the second direction DR2, which are the horizontal directions. For example, the first diagonal direction DD1 may be a direction inclined by 45° with respect to each of the first direction DR1 and the second direction DR2, but is not limited thereto. The second diagonal direction DD2 crosses each of the first direction DR1 and the second direction DR2, which are the horizontal directions. For example, the second diagonal direction DD2 may be a direction inclined by 45° with respect to each of a direction opposite to the first direction DR1 and the second direction DR2, but is not limited thereto. The second diagonal direction DD2 may be a direction orthogonal to the first diagonal direction DD1.

It has been illustrated in FIGS. 5 and 6 that each of the plurality of pixels PX includes three emission areas EA, but an embodiment of the present disclosure is not limited thereto. According to another embodiment, each of the plurality of pixels PX may include four or more emission areas EA.

Each emission area EA included in the plurality of pixels PX may be positioned to be surrounded by each trench TRC. The trench TRC will be described later.

FIG. 7 is a cross-sectional view illustrating an example of the display panel taken along X1-X1′ of FIG. 5.

Referring to FIG. 7, the display panel 100 may include a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 (see FIG. 3) described with reference to FIG. 3.

The semiconductor substrate SSUB may be replaced with a glass substrate or a polymer resin substrate such as a polyimide substrate. In this case, thin film transistors may be disposed on the glass substrate or the polymer resin substrate. The glass substrate may be a rigid substrate that is not bent, and the polymer resin substrate may be a flexible substrate that may be bent or curved.

The semiconductor substrate SSUB may be a substrate doped with first-type impurities. A plurality of well regions WA may be disposed in an upper surface of the semiconductor substrate SSUB. The plurality of well regions WA may be regions doped with second-type impurities. The second-type impurities may be different from the first-type impurities described above. For example, when the first-type impurities are p-type impurities, the second-type impurities may be n-type impurities. Alternatively, when the first-type impurities are n-type impurities, the second-type impurities may be p-type impurities.

Each of the plurality of well regions WA may include a source region SA corresponding to a source electrode of the pixel transistor PTR, a drain region DA corresponding to a drain electrode of the pixel transistor PTR, and a channel region CH disposed between the source region SA and the drain region DA.

A bottom insulating film BINS may be disposed between a gate electrode GE and the well region WA. Side surface insulating films SINS may be disposed on side surfaces of the gate electrode GE. The side surface insulating films SINS may be disposed on the bottom insulating film BINS.

Each of the source region SA and the drain region DA may be a region doped with the first-type impurities. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA may further include a first low-concentration impurity region LDD1 disposed between the channel region CH and the source region SA and a second low-concentration impurity region LDD2 disposed between the channel region CH and the drain region DA. The first low-concentration impurity region LDD1 may be a region having a lower impurity concentration than the source region SA due to the bottom insulating film BINS. The second low-concentration impurity region LDD2 may be a region having a lower impurity concentration than the drain region DA due to the bottom insulating film BINS. A distance between the source region SA and the drain region DA may increase by the first low-concentration impurity region LDD1 and the second low-concentration impurity region LDD2. Therefore, a length of the channel region CH of each of the pixel transistors PTR increases, and thus, punch-through and hot carrier phenomena caused by a short channel is prevented.

A first semiconductor insulating film SINS1 may be disposed on the semiconductor substrate SSUB. The first semiconductor insulating film SINS1 may be formed as a silicon carbonitride (SiCN) or silicon oxide (SiOₓ)-based inorganic film, but an embodiment of the present disclosure is not limited thereto.

A second semiconductor insulating film SINS2 may be disposed on the first semiconductor insulating film SINS1. The second semiconductor insulating film SINS2 may be formed as a silicon oxide (SiOₓ)-based inorganic film, but an embodiment of the present disclosure is not limited thereto.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through a hole penetrating through the first semiconductor insulating film SINS1 and the second semiconductor insulating film SINS2. Each of the plurality of contact terminals CTE may be made of any one of copper (Cu), aluminum (Al), tungsten (W), molybdenum (Mo), chromium (Cr), gold (Au), titanium (Ti), nickel (Ni), and neodymium (Nd), or alloys thereof.

A third semiconductor insulating film SINS3 may be disposed on side surfaces of each of the plurality of contact terminals CTE. An upper surface of each of the plurality of contact terminals CTE may be exposed without being covered by the third semiconductor insulating film SINS3. The third semiconductor insulating film SINS3 may be formed as a silicon oxide (SiOₓ)-based inorganic film, but an embodiment of the present disclosure is not limited thereto.

The light emitting element backplane EBP may include a plurality of conductive layers ML1 to ML8, a plurality of vias VA1 to VA9, and a plurality of insulating films INS1 to INS9.

First to eighth conductive layers ML1 to ML8 serve to implement a pixel circuit of the first sub-pixel SP1 illustrated in FIG. 3 by connecting the plurality of contact terminals CTE exposed from the semiconductor backplane SBP to each other. For example, only the first to sixth transistors T1 to T6 are formed in the semiconductor backplane SBP, and connection lines of the first to sixth transistors T1 to T6 and the first capacitor CP1 and the second capacitor CP2 may be disposed in the first to eighth conductive layers ML1 to ML8. In addition, a connection portion between a drain region corresponding to the drain electrode of the fourth transistor T4, a source region corresponding to the source electrode of the fifth transistor T5, and the first electrode of the light emitting element LE may also be disposed in the first to eighth conductive layers ML1 to ML8.

A first insulating film INS1 may be disposed on the semiconductor backplane SBP. Each of first vias VA1 may penetrate through the first film INS1 to be connected to the contact terminal CTE exposed from the semiconductor backplane SBP. Each of the first conductive layers ML1 may be disposed on the first insulating film INS1 and connected to the first via VA1.

A second insulating film INS2 may be disposed on the first insulating film INS1 and the first conductive layers ML1. Each of second vias VA2 may penetrate through the second insulating film INS2 to be connected to the exposed first conductive layer ML1. Each of the second conductive layers ML2 may be disposed on the second insulating film INS2 and connected to the second via VA2.

A third insulating film INS3 may be disposed on the second insulating film INS2 and the second conductive layers ML2. Each of third vias VA3 may penetrate through the third insulating film INS3 to be connected to the exposed second conductive layer ML2. Each of the third conductive layers ML3 may be disposed on the third insulating film INS3 and connected to the third via VA3.

A fourth insulating film INS4 may be disposed on the third insulating film INS3 and the third conductive layer ML3. Each of fourth vias VA4 may penetrate through the fourth insulating film INS4 to be connected to the exposed third conductive layer ML3. Each of the fourth conductive layers ML4 may be disposed on the fourth insulating film INS4 and connected to the fourth via VA4.

A fifth insulating film INS4 may be disposed on the fourth insulating film INS4 and the fourth conductive layers ML4. Each of fifth vias VA5 may penetrate through the fifth film INS5 to be connected to the exposed fourth conductive layer ML4. Each of the fifth conductive layers ML5 may be disposed on the fifth insulating film INS5 and connected to the fifth via VA5.

A sixth insulating film INS6 may be disposed on the fifth insulating film INS5 and the fifth conductive layer ML5. Each of sixth vias VA6 may penetrate through the sixth insulating film INS6 to be connected to the exposed fifth conductive layer ML5. Each of the sixth conductive layers ML6 may be disposed on the sixth insulating film INS6 and connected to the sixth via VA6.

A seventh insulating film INS7 may be disposed on the sixth insulating film INS6 and the sixth conductive layer ML6. Each of seventh vias VA7 may penetrate through the seventh insulating film INS7 to be connected to the exposed sixth conductive layer ML6. Each of the seventh conductive layers ML7 may be disposed on the seventh insulating film INS7 and connected to the seventh via VA7.

An eighth insulating film INS8 may be disposed on the seventh insulating film INS7 and the seventh conductive layer ML7. Each of eighth vias VA8 may penetrate through the eighth insulating film INS8 to be connected to the exposed seventh conductive layer ML7. Each of the eighth conductive layers ML8 may be disposed on the eighth insulating film INS8 and connected to the eighth via VA8.

The first to eighth conductive layers ML1 to ML8 and the first to eighth vias VA1 to VA8 may be made of substantially the same material. Each of the first to eighth conductive layers ML1 to ML8 and the first to eighth vias VA1 to VA8 may be made of any one of copper (Cu), aluminum (Al), tungsten (W), molybdenum (Mo), chromium (Cr), gold (Au), titanium (Ti), nickel (Ni), and neodymium (Nd), or alloys thereof. The first to eighth insulating films INS1 to INS8 may be formed as silicon oxide (SiOₓ)-based inorganic films, but an embodiment of the present disclosure is not limited thereto.

Each of a thickness of the first conductive layer ML1, a thickness of the second conductive layer ML2, a thickness of the third conductive layer ML3, a thickness of the fourth conductive layer ML4, a thickness of the fifth conductive layer ML5, and a thickness of the sixth conductive layer ML6 may be greater than each of a thickness of the first via VA1, a thickness of the second via VA2, a thickness of the third via VA3, a thickness of the fourth via VA4, a thickness of the fifth via VA5, and a thickness of the sixth via VA6. Each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same as each other. For example, the thickness of the first conductive layer ML1 is approximately 1360 angstroms (Å), each of the thickness of the second conductive layer ML2, the thickness of the third conductive layer ML3, the thickness of the fourth conductive layer ML4, the thickness of the fifth conductive layer ML5, and the thickness of the sixth conductive layer ML6 is approximately 1440 Å, and each of the thickness of the first via VA1, the thickness of the second via VA2, the thickness of the third via VA3, the thickness of the fourth via VA4, the thickness of the fifth via VA5, and the thickness of the sixth via VA6 is approximately 1150 Å. However, the thicknesses of the first to sixth conductive layers ML1, ML2, ML3, ML4, ML5, and ML6 and the first to sixth vias VA1, VA2, VA3, VA4, VA5, and VA6 are not limited thereto.

Each of a thickness of the seventh conductive layer ML7 and a thickness of the eighth conductive layer ML8 may be greater than each of the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. Each of the thickness of the seventh conductive layer ML7 and the eighth conductive layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same as each other. For example, each of the thickness of the seventh conductive layer ML7 and the eighth conductive layer ML8 is approximately 9000 Å, and each of the thickness of the seventh via VA7 and the thickness of the eighth via VA8 is approximately 6000 Å. However, the thicknesses of the seventh conductive layer ML7, the eighth conductive layer ML8, the seventh via VA7, and the eighth via VA8 are not limited thereto.

A ninth insulating film INS9 may be disposed on the eighth insulating film INS8 and the eighth conductive layer ML8. The ninth insulating film INS9 may be formed as a silicon oxide (SiOₓ)-based inorganic film, but an embodiment of the present disclosure is not limited thereto.

Each of ninth vias VA9 may penetrate through the ninth insulating film INS9 to be connected to the exposed eighth conductive layer ML8. Each of the ninth vias VA9 may be made of any one of copper (Cu), aluminum (Al), tungsten (W), molybdenum (Mo), chromium (Cr), gold (Au), titanium (Ti), nickel (Ni), and neodymium (Nd), or alloys thereof.

The display element layer EML may be disposed on the light emitting element backplane EBP. The display element layer EML may include light emitting elements LE, a pixel defining film PDL, and a plurality of trenches TRC. Each of the light emitting elements LE may include a reflective electrode layer RL, tenth and eleventh insulating films INS10 and INS11, a tenth via VA10, a first electrode AND, a light emitting layer IL, and a second electrode CAT.

The reflective electrode layer RL may be disposed on the ninth insulating film INS9. The reflective electrode layer RL may include one or more reflective electrodes RL1, RL2, RL3, and RL4. For example, the reflective electrode layer RL may include first to fourth reflective electrodes RL1, RL2, RL3, and RL4 as illustrated in FIG. 7, but is not limited thereto.

Each of the first reflective electrodes RL1 may be disposed on the ninth insulating film INS9 and connected to the ninth via VA9. Each of the first reflective electrodes RL1 may be made of any one of copper (Cu), aluminum (Al), tungsten (W), molybdenum (Mo), chromium (Cr), gold (Au), titanium (Ti), nickel (Ni), and neodymium (Nd), or alloys thereof. For example, each of the first reflective electrodes RL1 may include titanium nitride (TiN).

Each of the second reflective electrodes RL2 may be disposed on the first reflective electrode RL1. Each of the second reflective electrodes RL2 may be made of any one of copper (Cu), aluminum (Al), tungsten (W), molybdenum (Mo), chromium (Cr), gold (Au), titanium (Ti), nickel (Ni), and neodymium (Nd), or alloys thereof. For example, each of the second reflective electrodes RL2 may include aluminum (Al).

Each of the third reflective electrodes RL3 may be disposed on the second reflective electrode RL2. Each of the third reflective electrodes RL3 may be made of any one of copper (Cu), aluminum (Al), tungsten (W), molybdenum (Mo), chromium (Cr), gold (Au), titanium (Ti), nickel (Ni), and neodymium (Nd), or alloys thereof. For example, each of the third reflective electrodes RL3 may include titanium nitride (TiN).

Each of the fourth reflective electrodes RL4 may be disposed on the third reflective electrode RL3. Each of the fourth reflective electrodes RL4 may be made of any one of copper (Cu), aluminum (Al), tungsten (W), molybdenum (Mo), chromium (Cr), gold (Au), titanium (Ti), nickel (Ni), and neodymium (Nd), or alloys thereof. For example, each of the fourth reflective electrodes RL4 may include titanium (Ti).

Since the second reflective electrodes RL2 are electrodes substantially reflecting light from the light emitting elements LE, a thickness of the second reflective electrode RL2 may be greater than a thickness of the first reflective electrode RL1, a thickness of the third reflective electrode RL3, and a thickness of the fourth reflective electrode RL4. For example, each of the thickness of the first reflective electrode RL1, the third reflective electrode RL3, and the fourth reflective electrode RL4 is approximately 100 Å, and the thickness of the second reflective electrode RL2 is approximately 850 Å. However, the thicknesses of the first to fourth reflective electrodes RL1, RL2, RL3, and RL4 are not limited thereto.

The tenth insulating film INS10 may be disposed on the ninth insulating film INS9. The tenth insulating film INS10 may be disposed between the reflective electrode layers RL adjacent to each other in a horizontal direction. The tenth insulating film INS10 may be formed as a silicon oxide (SiOₓ)-based inorganic film, but an embodiment of the present disclosure is not limited thereto. In some embodiments, although not illustrated in FIG. 7, the tenth insulating film INS10 may be disposed not only between the reflective electrode layers RL but also on the reflective electrode layer RL.

The eleventh insulating film INS11 may be disposed on the tenth insulating film INS10 and the reflective electrode layer RL. The eleventh insulating film INS11 may be formed as a silicon oxide (SiOₓ)-based inorganic film, but an embodiment of the present disclosure is not limited thereto. The tenth insulating film INS10 and the eleventh insulating film INS11 may be optical auxiliary layers through which light reflected by the reflective electrode layer RL among light emitted from the light emitting elements LE passes in another embodiment.

In some embodiment, in at least one of the first sub-pixel SP1, the second sub-pixel SP2, or the third sub-pixel SP3, total thicknesses of the insulating films disposed between the first electrodes AND and the reflective electrode layers RL of the first sub-pixel SP1, the second sub-pixel SP2, and the third sub-pixel SP3 may be different from each other in order adjust a resonance distance of the light emitted from the light emitting elements LE.

In an embodiment, as illustrated in FIG. 7, when the tenth insulating film INS10 is not disposed between the first electrode AND and the reflective electrode layer RL and the eleventh insulating film INS11 is disposed between the first electrode AND and the reflective electrode layer RL, thicknesses of the eleventh insulating films INS11 disposed in the first sub-pixel SP1, the second sub-pixel SP2, and the third sub-pixel SP3, respectively, may be different from each other. For example, a thickness of the eleventh insulating film INS11 disposed in the first sub-pixel SP1 may be smaller than a thickness of the eleventh insulating film INS11 disposed in the second sub-pixel SP2, and the thickness of the eleventh insulating film INS11 disposed in the second sub-pixel SP2 may be smaller than a thickness of the eleventh insulating film INS11 disposed in the third sub-pixel SP3.

In another embodiment, both the tenth insulating film INS10 and the eleventh insulating film INS11 may not be disposed between the first electrode AND and the reflective electrode layer RL in the first sub-pixel SP1, any one of the tenth insulating film INS10 and the eleventh insulating film INS11 may be disposed between the first electrode AND and the reflective electrode layer RL in the second sub-pixel SP2, and both the tenth insulating film INS10 and the eleventh insulating film INS11 may be disposed between the first electrode AND and the reflective electrode layer RL in the third sub-pixel SP3.

In still another embodiment, a twelfth insulating film may be further disposed between the first electrode AND and the reflective electrode layer RL. In this case, any one of the tenth insulating film INS10, the eleventh insulating film INS11, and the twelfth insulating film may be disposed between the first electrode AND and the reflective electrode layer RL in the first sub-pixel SP1, any two of the tenth insulating film INS10, the eleventh insulating film INS11, and the twelfth insulating film may be disposed between the first electrode AND and the reflective electrode layer RL in the second sub-pixel SP2, and all of the tenth insulating film INS10, the eleventh insulating film INS11, and the twelfth insulating film may be disposed between the first electrode AND and the reflective electrode layer RL in the third sub-pixel SP3.

In summary, a distance between the first electrode AND and the reflective electrode layer RL may be different in each of the first sub-pixel SP1, the second sub-pixel SP2, and the third sub-pixel SP3. That is, in order to adjust a distance from the reflective electrode layer RL to the second electrode CAT according to a main wavelength of light emitted from each of the first sub-pixel SP1, the second sub-pixel SP2, and third the sub-pixel SP3, the presence or absence or thicknesses of the tenth interlayer insulating film INS10 and the eleventh interlayer insulating film INS11 may be set in each of the first sub-pixel SP1, the second sub-pixel SP2, and the third sub-pixel SP3.

It has been illustrated in FIG. 7 that the total thicknesses of the insulating films disposed between the first electrodes AND and the reflective electrode layers RL are greater in the order of the first sub-pixel SP1, the second sub-pixel SP2, and the third sub-pixel SP3, but the present disclosure is not limited thereto. That is, it has been illustrated that a distance between the first electrode AND and the reflective electrode layer RL in the third sub-pixel SP3 is greater than a distance between the first electrode AND and the reflective electrode layer RL in the second sub-pixel SP2 and a distance between the first electrode AND and the reflective electrode layer RL in the first sub-pixel SP1 and the distance between the first electrode AND and the reflective electrode layer RL in the second sub-pixel SP2 is greater than the distance between the first electrode AND and the reflective electrode layer RL in the first sub-pixel SP1, but an embodiment of the present disclosure is not limited thereto. A size relationship between the total thicknesses of the insulating films between the first electrodes AND and the reflective electrode layers RL in the first sub-pixel SP1, the second sub-pixel SP2, and the third sub-pixel SP3 may be variously modified depending on the resonance distance.

Each of the tenth vias VA10 may be made of any one of copper (Cu), aluminum (Al), tungsten (W), molybdenum (Mo), chromium (Cr), gold (Au), titanium (Ti), nickel (Ni), and neodymium (Nd), or alloys thereof. A thickness of the tenth via VA10 in the second sub-pixel SP2 may be smaller than a thickness of the tenth via VA10 in the third sub-pixel SP3, and a thickness of the tenth via VA10 in the first sub-pixel SP1 may be smaller than the thickness of the tenth via VA10 in the second sub-pixel SP2, but the present disclosure is not limited thereto.

The first electrode AND of each of the light emitting elements LE may be disposed on the eleventh insulating film INS11 and connected to the tenth via VA10. The first electrode AND of each of the light emitting elements LE may be connected to the drain region DA or the source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be made of any one of copper (Cu), aluminum (Al), tungsten (W), molybdenum (Mo), chromium (Cr), gold (Au), titanium (Ti), nickel (Ni), and neodymium (Nd), or alloys thereof. For example, the first electrode AND of each of the light emitting elements LE may be made of titanium nitride (TiN).

The pixel defining film PDL may be disposed on a partial area of the first electrode AND of each of the light emitting elements LE. The pixel defining film PDL may cover an edge of the first electrode AND of each of the light emitting elements LE. The pixel defining film PDL serves to partition the respective first emission areas EA1, second emission areas EA2, and third emission areas EA3.

The first emission area EA1 may be defined as an area where the first electrode AND, the light emitting layer IL, and the second electrode CAT are sequentially stacked in the first sub-pixel SP1 to emit light. The second emission area EA2 may be defined as an area where the first electrode AND, the light emitting layer IL, and the second electrode CAT are sequentially stacked in the second sub-pixel SP2 to emit light. The third emission area EA3 may be defined as an area where the first electrode AND, the light emitting layer IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed as silicon oxide (SiOₓ)-based inorganic films, but an embodiment of the present disclosure is not limited thereto. Each of a thickness of the first pixel defining film PDL1, a thickness of the second pixel defining film PDL2, and a thickness of the third pixel defining film PDL3 may be approximately 500 Å.

When the first pixel defining film PDL1, the second pixel defining film PDL2, and the third pixel defining film PDL3 are formed as one pixel defining film, a height of the one pixel defining film increases, such that a first encapsulation layer TFE1 may be disconnected due to step coverage. The step coverage refers to a ratio of a degree at which a thin film is coated on an inclined portion to a degree at which a thin film is coated on a flat portion. The lower the step coverage, the more likely it is that the thin film will be disconnected at the inclined portion.

Therefore, in order to prevent the first encapsulation layer TFE1 from being disconnected due to the step coverage, the first pixel defining film PDL1, the second pixel defining film PDL2, and the third pixel defining film PDL3 may have a cross-sectional structure with a step having a staircase shape. For example, a width of the first pixel defining film PDL1 may be greater than a width of the second pixel defining film PDL2 and a width of the third pixel defining film PDL3, and the width of the second pixel defining film PDL2 may be greater than the width of the third pixel defining film PDL3. The width of the first pixel defining film PDL1, the width of the second pixel defining film PDL2, and the width of the third pixel defining film PDL3 refer to a length of the first pixel defining film PDL1, a length of the second pixel defining film PDL2, and a length of the third pixel defining film PDL3 in the horizontal direction perpendicular to the third direction DR3, respectively.

Each of the plurality of trenches TRC may penetrate through the first pixel defining film PDL1, the second pixel defining film PDL2, and the third pixel defining film PDL3. In addition, each of the plurality of trenches TRC may penetrate through the eleventh insulating film INS11. In each of the plurality of trenches TRC, the eleventh insulating film INS11 may have a shape in which a portion thereof is trenched.

At least one trench TRC may be disposed between the first to third sub-pixels SP1, SP2, and SP3 neighboring to each other. It has been illustrated in FIG. 7 that two trenches TRC are disposed between the first to third sub-pixels SP1, SP2, and SP3 neighboring to each other, but an embodiment of the present disclosure is not limited thereto.

The light emitting layer IL may include a plurality of intermediate layers. It has been illustrated in FIG. 7 that the light emitting layer IL has a three-tandem structure including a first stack layer IL1, a second stack layer IL2, and a third stack layer IL3, but an embodiment of the present disclosure is not limited thereto. For another example, the light emitting layer IL may have a two-tandem structure including two intermediate layers.

In the three-tandem structure, the light emitting layer IL may have a tandem structure including a plurality of first to third stack layers IL1, IL2, and IL3 emitting different light. For example, the light emitting layer IL may include the first stack layer IL1 emitting light of a first color, the second stack layer IL2 emitting light of a third color, and the third stack layer IL3 emitting light of a second color. The first stack layer IL1, the second stack layer IL2, and the third stack layer IL3 may be sequentially stacked.

The first stack layer IL1 may have a structure in which a first hole transporting layer, a first organic light emitting layer emitting the light of the first color, and a first electron transporting layer are sequentially stacked. The second stack layer IL2 may have a structure in which a second hole transporting layer, a second organic light emitting layer emitting the light of the third color, and a second electron transporting layer are sequentially stacked. The third stack layer IL3 may have a structure in which a third hole transporting layer, a third organic light emitting layer emitting the light of the second color, and a third electron transporting layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer supplying electrons to the first stack layer IL1 and a P-type charge generation layer supplying holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer supplying electrons to the second stack layer IL2 and a P-type charge generation layer supplying holes to the third stack layer IL3.

The first stack layer IL1 may be disposed on the first electrodes AND and the pixel defining film PDL, and may be disposed on a bottom surface of each of the trenches TRC. Due to the trenches TRC, the first stack layer IL1 may be disconnected between the first to third sub-pixels SP1, SP2, and SP3 neighboring to each other. The second stack layer IL2 may be disposed on the first stack layer IL1. Due to the trenches TRC, the second stack layer IL2 may be disconnected between the first to third sub-pixels SP1, SP2, and SP3 neighboring to each other. A cavity ESS or an empty space may be disposed between the first stack layer IL1 and the second stack layer IL2. The third stack layer IL3 may be disposed on the second stack layer IL2. The third stack layer IL3 may not be disconnected by the trenches TRC, and may be disposed to cover the second stack layer IL2 in each of the trenches TRC. That is, in the three-tandem structure, each of the plurality of trenches TRC may be a structure for disconnecting the first and second stack layers IL1 and IL2, the first charge generation layer, and the second charge generation layer of the display element layer EML between the first to third sub-pixels SP1, SP2, and SP3 neighboring to each other. In addition, in the two-tandem structure, each of the plurality of trenches TRC may be a structure for disconnecting a charge generation layer disposed between a lower intermediate layer and an upper intermediate layer and the lower intermediate layer.

A height of each of the plurality of trenches TRC may be greater than a height of the pixel defining film PDL. This may be for stably disconnecting the first and second stack layers IL1 and IL2 of the display element layer EML between the first to third sub-pixels SP1, SP2, and SP3 neighboring to each other.

The height of each of the plurality of trenches TRC refers to a length of each of the plurality of trenches TRC in the third direction DR3. The height of the pixel defining film PDL refers to a length of the pixel defining film PDL in the third direction DR3. In order to disconnect the first and second stack layers IL1 and IL2 of the display element layer EML between the first to third sub-pixels SP1, SP2, and SP3 neighboring to each other, other structures may exist instead of the trenches TRC. For example, instead of the trenches TRC, partition walls having a reverse tapered shape may be disposed on the pixel defining film PDL.

The number of first to third stack layers IL1, IL2, and IL3 emitting the different light is not limited to that illustrated in FIG. 7. For another example, the light emitting layer IL may include two intermediate layers. In this case, any one of the two intermediate layers may be substantially the same as the first stack layer IL1, and the other of the two intermediate layers may include a second hole transporting layer, a second organic light emitting layer, a third organic light emitting layer, and a second electron transporting layer. In this case, a charge generation layer for supplying electrons to any one intermediate layer and supplying charges to the other intermediate layer may be disposed between the two intermediate layers.

It has been illustrated in FIG. 7 that the first to third stack layers IL1, IL2, and IL3 are disposed in all of the first emission area EA1, the second emission area EA2, and the third emission area EA3, but an embodiment of the present disclosure is not limited thereto. For another example, the first stack layer IL1 may be disposed in the first emission area EA1, and may not be disposed in the second emission area EA2 and the third emission area EA3. In addition, the second stack layer IL2 may be disposed in the second emission area EA2, and may not be disposed in the first emission area EA1 and the third emission area EA3. In addition, the third stack layer IL3 may be disposed in the third emission area EA3, and may not be disposed on the first emission area EA1 and the second emission area EA2. In this case, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC.

The second electrode CAT may be made of a transparent conductive material (TCO) such as indium tin oxide (ITO) or indium zinc oxide (IZO) capable of transmitting light therethrough or a semi-transmissive conductive material such as magnesium (Mg), silver (Ag), or an alloy of magnesium (Mg) and silver (Ag). When the second electrode CAT is made of the semi-transmissive conductive material, light emission efficiency of each of the first to third sub-pixels SP1, SP2, and SP3 may be increased by a micro cavity.

The encapsulation layer TFE may be disposed on the display element layer EML. The encapsulation layer TFE may include at least one inorganic film TFE1 or TFE2 in order to prevent oxygen or moisture from permeating into the display element layer EML. For example, the encapsulation layer TFE may include a first encapsulation layer TFE1 and a second encapsulation layer TFE2.

The first encapsulation layer TFE1 may be disposed on the second electrode CAT. The first encapsulation layer TFE1 may be formed as multiple films in which one or more inorganic films of a silicon nitride (SiNₓ) layer, a silicon oxynitride (SiON) layer, and a silicon oxide (SiOₓ) layer are alternately stacked. The first encapsulation layer TFE1 may be formed by a chemical vapor deposition (CVD) process.

The second encapsulation layer TFE2 may be disposed on the first encapsulation layer TFE1. The second encapsulation layer TFE2 may be formed as a titanium oxide (TiOₓ) layer or an aluminum oxide (AlOₓ) layer, but an embodiment of the present disclosure is not limited thereto. The second encapsulation layer TFE2 may be formed by an atomic layer deposition (ALD) process. A thickness of the second encapsulation layer TFE2 may be smaller than a thickness of the first encapsulation layer TFE1.

The display panel 100 may further include an organic film APL. The organic film APL may be a layer for increasing interfacial adhesive strength between the encapsulation layer TFE and the optical layer OPL.

The organic film APL may be an organic film made of an acrylic resin, an epoxy resin, a phenolic resin, a polyamide resin, a polyimide resin, or the like.

The optical layer OPL may include a plurality of first to third color filters CF1, CF2, and CF3, a plurality of lenses LNS, and a filling layer FIL.

The first to third color filters CF1, CF2, and CF3 may be disposed on the organic film APL.

The first color filter CF1 may overlap the first emission area EA1 of the first sub-pixel SP1. The first color filter CF1 may transmit the light of the first color, that is, the light of the red wavelength band, therethrough. The red wavelength band may be a wavelength band of approximately 600 nm to 750 nm. Therefore, the first color filter CF1 may transmit the light of the first color among light emitted from the first emission area EA1 therethrough.

The second color filter CF2 may overlap the second emission area EA2 of the second sub-pixel SP2. The second color filter CF2 may transmit the light of the second color, that is, the light of the green wavelength band, therethrough. The green wavelength band may be a wavelength band of approximately 480 nm to 560 nm. Therefore, the second color filter CF2 may transmit the light of the second color among light emitted from the second emission area EA2 therethrough.

The third color filter CF3 may overlap the third emission area EA3 of the third sub-pixel SP3. The third color filter CF3 may transmit the light of the third color, that is, the light of the blue wavelength band, therethrough. The blue wavelength band may be a wavelength band of approximately 370 nm to 460 nm. Therefore, the third color filter CF3 may transmit the light of the third color among light emitted from the third emission area EA3 therethrough.

Each of the plurality of lenses LNS may be disposed on each of the first color filter CF1, the second color filter CF2, and the third color filter CF3. Each of the plurality of lenses LNS may be a structure for increasing a ratio of light directed to a front surface of the display device 10. Each of the plurality of lenses LNS may have a cross-sectional shape convex in an upward direction. In some embodiments, the plurality of lenses LNS may be a micro lens array (MLA).

The filling layer FIL may be disposed on the plurality of lenses LNS. The filling layer FIL may have a predetermined refractive index so that light travels in the third direction DR3 at an interface between the plurality of lenses LNS and the filling layer FIL. In addition, the filling layer FIL may be a planarizing layer. The filling layer FIL may be an organic film made of an acrylic resin, an epoxy resin, a phenolic resin, a polyamide resin, a polyimide resin, or the like.

The cover layer CVL may be disposed on the filling layer FIL. The cover layer CVL may be a glass substrate or a polymer resin such as a resin. When the cover layer CVL is the glass substrate, the cover layer CVL may be attached onto the filling layer FIL. In this case, the filling layer FIL serves to adhere the cover layer CVL. When the cover layer CVL is the glass substrate, the cover layer CVL may serve as an encapsulation substrate. When the cover layer CVL is the polymer resin such as the resin, the cover layer CVL may be directly applied onto the filling layer FIL.

The polarizing plate POL may be disposed on one surface of the cover layer CVL. The polarizing plate POL may be a structure for preventing deterioration in visibility due to external light reflection. The polarizing plate POL may include a linear polarizing plate and a phase retardation film. For example, the phase retardation film may be a λ/4 plate (quarter-wave plate), but an embodiment of the present disclosure is not limited thereto. However, when visibility due to external light reflection is sufficiently improved by the first to third color filters CF1, CF2, and CF3, the polarizing plate POL may be omitted.

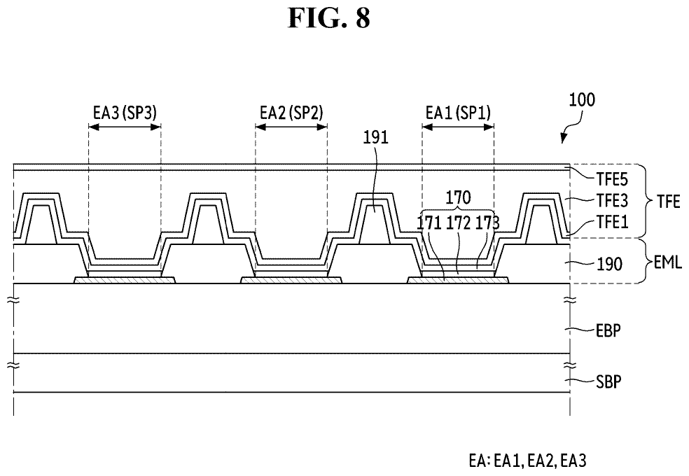

FIG. 8 is a cross-sectional view illustrating another example of a display panel included in the display device according to an embodiment.

A display panel 100 according to an embodiment of FIG. 8 may include a semiconductor backplane SBP, a light emitting element backplane EBP, a display element layer EML, and an encapsulation layer TFE. However, the display panel 100 according to an embodiment of FIG. 8 is not limited thereto, and may further include an optical layer OPL, a cover layer CVL, and a polarizing plate POL that are disposed on the encapsulation layer TFE, similar to the display panel 100 described with reference to FIG. 7.

The semiconductor backplane SBP and the light emitting element backplane EBP are the same as those of the display panel 100 described with reference to FIG. 7, and a description thereof is thus omitted.

The display element layer EML according to an embodiment of FIG. 8 may be disposed on the light emitting element backplane EBP. The display element layer EML may include light emitting elements 170 and a bank 190. Each of the light emitting elements 170 may include a first light emitting electrode 171, the light emitting layer 172, and a second light emitting electrode 173.

The first light emitting electrode 171 may be disposed on the light emitting element backplane EBP. For example, although not illustrated in FIG. 8, the first light emitting electrode 171 may be connected to the eighth conductive layer ML8 through the ninth via VA9 penetrating through the ninth insulating film INS9 and exposing the eighth conductive layer ML8.

In a top emission structure in which light is emitted toward the second light emitting electrode 173 based on the light emitting layer 172, the first light emitting electrode 171 may be made of a metal material having high reflectivity, such as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO. The APC alloy is an alloy of silver (Ag), palladium (Pd), and copper (Cu).

The bank 190 may be positioned on the first light emitting electrode 171. The bank 190 may serve to define the first to third emission areas EA1, EA2, and EA3. The bank 190 may be disposed to cover a portion of an edge of the first light emitting electrode 171.

The bank 190 may be formed as an organic film made of an acrylic resin, an epoxy resin, a phenolic resin, a polyamide resin, a polyimide resin, or the like.

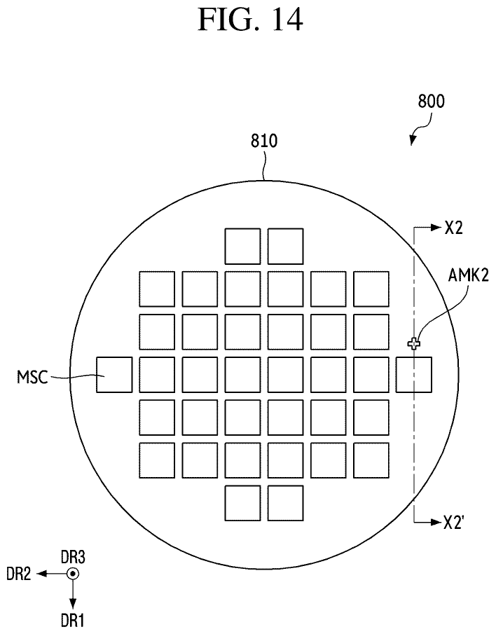

A spacer 191 may be disposed on the bank 190. The spacer 191 may serve to support a deposition mask 800 (see FIG. 14) during a process of manufacturing the light emitting layer 172.

The spacer 191 may be formed as an organic film made of an acrylic resin, an epoxy resin, a phenolic resin, a polyamide resin, a polyimide resin, or the like.

Each of the first to third emission areas EA1, EA2, and EA3 may refers to an emission area EA where the first light emitting electrode 171, the light emitting layer 172, and the second light emitting electrode 173 are sequentially stacked and holes from the first light emitting electrode 171 and electrons from the second light emitting electrode 173 are combined with each other in the light emitting layer 172 to emit light.

The light emitting layer 172 may be disposed on the first light emitting electrode 171 and the bank 190. The light emitting layer 172 may include an organic material to emit light of a predetermined color. For example, the light emitting layer 172 may include a hole transporting layer, an organic material layer, and an electron transporting layer.

The second light emitting electrode 173 may be disposed on the light emitting layer 172. The second light emitting electrode 173 may be formed to cover the light emitting layer 172. The second light emitting electrode 173 may be a common layer formed in common in all of the first to third emission areas EA1, EA2, and EA3. Although not illustrated in FIG. 8, in some embodiments, a capping layer may be formed on the second light emitting electrode 173.

In the top emission structure, the second light emitting electrode 173 may be made of transparent conductive oxide (TCO) such as ITO or IZO capable of transmitting light therethrough or a semi-transmissive conductive material such as magnesium (Mg), silver (Ag), or an alloy of magnesium (Mg) and silver (Ag). When the second light emitting electrode 173 is made of the semi-transmissive conductive material, light emission efficiency may be increased by a micro cavity.

The encapsulation layer TFE may be disposed on the second light emitting electrode 173. The encapsulation layer TFE may include at least one inorganic film in order to prevent oxygen or moisture from penetrating into the display element layer EML. In addition, the encapsulation layer TFE may include at least one organic film in order to protect the display element layer EML from foreign substances such as dust. For example, the encapsulation layer TFE may include a first encapsulation layer TFE1, a second encapsulation layer TFE2, and a third encapsulation layer TFE5.

The first encapsulation layer TFE1 (e.g., a first inorganic encapsulation film) may be disposed on the second light emitting electrode 173. The first encapsulation layer TFE1 may be a single-layer or multilayer inorganic film. The first encapsulation layer TFE1 may be formed as multiple films in which one or more inorganic films of a silicon nitride layer, a silicon oxynitride layer, a silicon oxide layer, a titanium oxide layer, and an aluminum oxide layer are alternately stacked or a single film.

The second encapsulation layer TFE2 (e.g., a first organic encapsulation film) may be disposed on the first encapsulation layer TFE1. The second encapsulation layer TFE2 may be a single-layer or multilayer organic film. The second encapsulation layer TFE2 may include a polymer-based material. The polymer-based material may include polyethylene terephthalate, polyethylene naphthalate, polycarbonate, polyimide, polyethylene sulfonate, polyoxymethylene, polyarylate, hexamethyldisiloxane, and an acrylic resin (e.g., polymethyl methacrylate, polyacrylic acid, etc.), or any combinations thereof.

The third encapsulation layer TFE5 (e.g., a second inorganic encapsulation film) may be disposed on the second encapsulation layer TFE2. The third encapsulation layer TFE5 may be a single-layer or multilayer inorganic film. The third encapsulation layer TFE5 may include the same material as the first encapsulation layer TFE1. For example, the third encapsulation layer TFE5 may be formed as multiple films in which one or more inorganic films of a silicon nitride layer, a silicon oxynitride layer, a silicon oxide layer, a titanium oxide layer, and an aluminum oxide layer are alternately stacked or a single film.

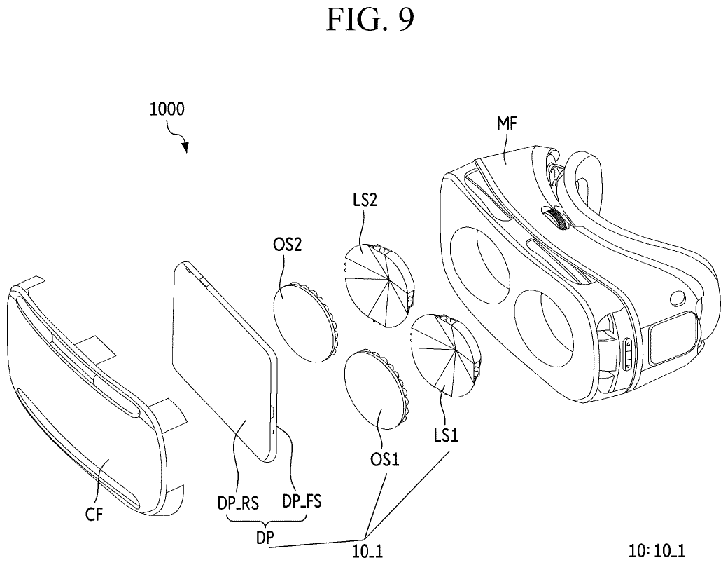

FIG. 9 is an exploded perspective view illustrating a head mounted display device according to an embodiment.

Referring to FIG. 9, a head mounted display device 1000 is formed in a glasses form or a head mounted form and provides an image to a user using a display device 10_1.

The head mounted display device 1000 may include a see-through type that provides augmented reality based on actual external objects, and a see-closed type that provides virtual reality to a user with a screen independent of external objects.

The head mounted display device 1000 may include a main frame MF mounted on a user's body, the display device 10_1 mounted on the main frame MF and displaying an image, and a cover frame CF covering the display device 10_1.

The display device 10_1 may be formed integrally with the head mounted display device 1000 that the user may carry and easily mount on or demount from his/her face or head or may be formed in a form in which it is assembled to the head mounted display device 1000. The display device 10_1 may be substantially the same as the display device 10 described with reference to FIG. 1 and the like.

The display device 10_1 may include a display panel DP displaying an image, first and second lens frames OS1 and OS2 refracting image display light, and first and second multi-channel lenses LS1 and LS2 forming light paths so that the image display light of the display panel DP is visible to the user.

The main frame MF may be worn on the user's face and head. The main frame MF may be formed in a shape corresponding to a structure of the user's head and face.

The display device 10_1, that is, the display panel DP, the first and second lens frames OS1 and OS2, and the first and second multi-channel lenses LS1 and LS2 may be formed integrally with the main frame MF. Alternatively, the display panel DP, the first and second lens frames OS1 and OS2, and the first and second multi-channel lenses LS1 and LS2 may be assembled to and mounted on the main frame MF. To this end, the main frame MF may include a space or structure in which the display panel DP, the first and second lens frames OS1 and OS2, and the first and second multi-channel lenses LS1 and LS2 may be accommodated. The main frame MF may further include a structure such as a strap or a band for easy mounting, and may further include a control unit, an image processing unit, a lens accommodating unit, and the like.

The display panel DP may be divided into a front surface DP_FS on which the image is displayed and a rear surface DP_RS positioned on a side opposite to the front surface DP_FS. The image display light may be emitted to the front surface DP_FS of the display panel DP. As described later, the first and second lens frames OS1 and OS2 may be disposed on the front surface DP_FS of the display panel DP, and the first and second multi-channel lenses LS1 and LS2 may be disposed on front surfaces of the first and second lens frames OS1 and OS2, respectively. Meanwhile, although not illustrated in FIG. 9, at least one infrared camera may be further disposed on at least one of the front surface DP_FS or the rear surface DP_RS of the display panel DP. The display panel DP may be substantially the same as the display panel 100 described with reference to FIG. 1 and the like.

The display panel DP may be embedded in the main frame MF or detachably assembled to the main frame MF, in a state in which the first and second lens frames OS1 and OS2 and the first and second multi-channel lenses LS1 and LS2 are mounted thereon and fixed thereto. The display panel DP may be configured to be opaque, transparent, or translucent according to a design of the display device 10_1, for example, a use form of the display device 10_1.

Each of the first and second lens frames OS1 and OS2 may have an area corresponding to an image display surface of the display panel DP and may be formed in a shape corresponding to the image display surface. In addition, the first and second lens frames OS1 and OS2 may be formed in areas and shapes corresponding to shapes of rear surfaces of the first and second multi-channel lenses LS1 and LS2, respectively. Rear surfaces of the first and second lens frames OS1 and OS2 may be attached to the image display surface of the display panel DP, and the first and second multi-channel lenses LS1 and LS2 may be attached to the front surfaces of the first and second lens frames OS1 and OS2, respectively. Such first and second lens frames OS1 and OS2 refract the image display light emitted from the image display surface of the display panel DP at a preset angle and provide the refracted image display light to the first and second multi-channel lenses LS1 and LS2 disposed on the front surfaces thereof, respectively.

Specifically, the first and second lens frames OS1 and OS2 may refract the image display light emitted in a front direction from the image display surface of the display panel DP in an outer direction (or an outer circumferential direction) as compared with the front direction and provide the refracted image display light to the first and second multi-channel lenses LS1 and LS2 disposed on the front surfaces thereof, respectively. In particular, the first and second lens frames OS1 and OS2 may refract the image display light incident on the rear surfaces thereof in the outer direction (or the outer circumferential direction) and provide the refracted image display light to the rear surfaces of the first and second multi-channel lenses LS1 and LS2, respectively.

The first and second multi-channel lenses LS1 and LS2 may form paths of the light emitted through the first and second lens frames OS1 and OS2 to allow the image display light to be visible to user's eyes in the front direction.

Each of the first and second multi-channel lenses LS1 and LS2 may provide a plurality of channels (or paths) through which the image display light emitted from the display panel DP passes. The plurality of channels may pass the image display light emitted from the display panel DP through different paths and provide the image display light to the user. The image display light emitted through the first and second lens frames OS1 and OS2 may be incident on the respective channels, and images magnified through the respective channels may be focused on the user's eyes.

The first and second multi-channel lenses LS1 and LS2 may be arranged on the front surfaces of the first and second lens frames OS1 and OS2 so as to correspond to positions of user's left and right eyes, respectively. The first and second multi-channel lenses LS1 and LS2 may be accommodated inside the main frame MF.

The first and second multi-channel lenses LS1 and LS2 may refract and/or reflect the image display light emitted through the first and second lens frames OS1 and OS2 at least once to form paths to the user's eyes. At least one infrared light source may be further disposed on one side of each of the first and second multi-channel lenses LS1 and LS2 facing the main frame MF or user's eyeballs.

The cover frame CF may be disposed in a rear surface DP_RS direction of the display panel DP so as to cover the display panel DP, to protect the display panel DP. The cover frame CF may cover the display panel DP and be mounted on the main frame MF.

Although not illustrated in FIG. 9, the display device 10_1 may further include a control unit controlling an overall operation of the display device 10_1 including the display panel DP. The control unit may control an image display operation, an audio device, and the like, of the display panel DP. Specifically, the control unit performs image processing (e.g., image mapping) according to image display paths and a magnification according to the first and second lens frames OS1 and OS2 and the first and second multi-channel lenses LS1 and LS2, and controls the display panel DP to display the mapped image. The control unit may be implemented as a dedicated processor including an embedded processor or the like and/or a general-purpose processor including a central processing unit or an application processor, but is not limited thereto.

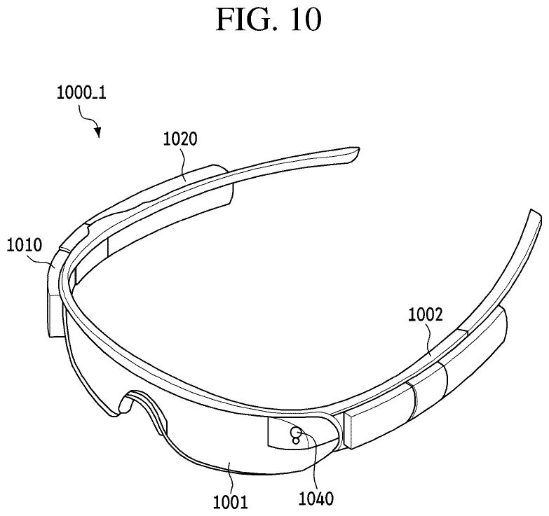

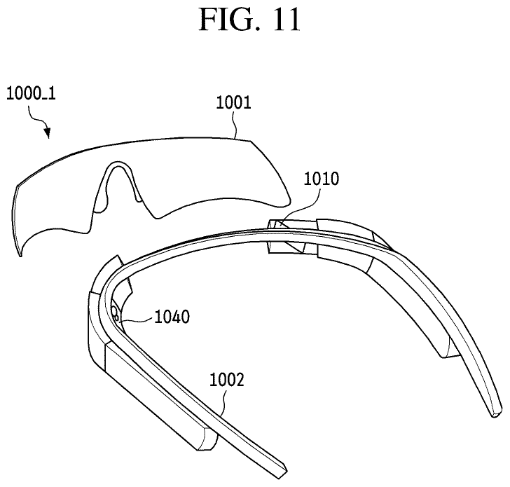

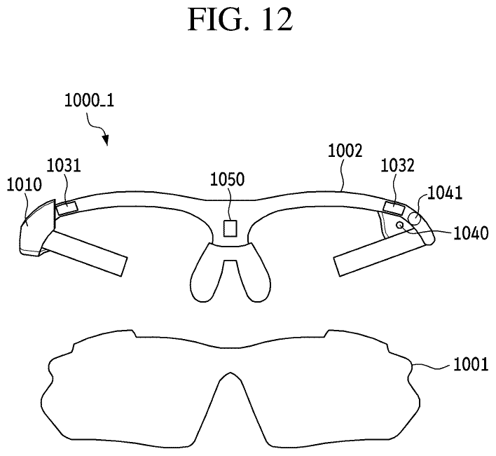

FIG. 10 is a perspective view illustrating an augmented reality content providing device according to an embodiment. FIG. 11 is an exploded perspective view of the augmented reality content providing device of FIG. 10 viewed in a rear surface direction, and FIG. 12 is an exploded perspective view of the augmented reality content providing device of FIG. 10 viewed in a front surface direction.

Referring to FIGS. 10 to 12, an augmented reality content providing device 1000_1 may include a support frame 1002 supporting at least one transparent lens 1001, at least one image display module 1010, a surrounding environment detection unit 1040, and a control module 1020.

The support frame 1002 may be formed in the shape of glasses including a glasses frame supporting an edge of at least one transparent lens 1001 and glasses temples. A shape of the support frame 1002 is not limited to the shape of glasses, but may also be a goggle shape or a head mounted shape including a transparent lens 1001 in another embodiment.

The transparent lens 1001 may be formed as an integral lens in left and right directions or configured as first and second transparent lenses separated from each other in the left and right directions. The transparent lens 1001 formed as the integral lens in the left and right directions or configured as the first and second transparent lenses separated from each other may be made of glass or plastic so as to be transparent or translucent. For this reason, a user may see a real image through the transparent lens 1001 formed as the integral lens in the left and right directions or configured as the first and second transparent lenses separated from each other. Here, the transparent lens 1001, that is, the integral lens or the first and second transparent lenses may have refractive power in consideration of a user's eyesight.

The transparent lens 1001 may further include at least one reflective member reflecting an augmented reality content image provided from at least one image display module 1010 toward the transparent lens 1001 or the user's eyes and optical members adjusting a focus and a size. At least one reflective member may be embedded in the transparent lens 1001 integrally with the transparent lens 1001, and may be formed as a plurality of refractive lenses or a plurality of prisms having a predetermined curvature.

At least one image display module 1010 may include a micro LED display device (micro-LED), a nano LED display device (nano-LED), an organic light emitting display device (OLED), an inorganic light emitting display device (inorganic EL), a quantum dot light emitting display device (QED), a cathode ray display (CRT), a liquid crystal display (LCD), and the like. The image display module 1010 may substantially include the display device 10 described with reference to FIG. 1 and the like.

The surrounding environment detection unit 1040 is assembled to or formed integrally with the support frame 1002 and detects a distance (or a depth) to an object of a front surface direction of the support frame 1002, illuminance, a moving direction, a moving distance, and a tilt of the support frame 1002, and the like. To this end, the surrounding environment detection unit 1040 includes a depth sensor 1041 such as an infrared sensor or a light detection and ranging (LiDAR) sensor, and an image sensor 1050 such as a camera. In addition, the surrounding environment detection unit 1040 may further include at least one motion sensor of an illuminance sensor, a human body detection sensor, a gyro sensor, a tilt sensor, and an acceleration sensor. Further, the surrounding environment detection unit 1040 may further include first and second biometric sensors 1031 and 1032 detecting movement information of user's eyeballs or pupils.

The surrounding environment detection unit 1040 may transmit sensing signals generated through the depth sensor 1041, at least one motion sensor, and the like, to the control module 1020 in real time. In addition, the image sensor 1050 may transmit image data in at least one frame unit generated in real time to the control module 1020. The first and second biometric sensors 1031 and 1032 of the surrounding environment detection unit 1040 may transmit pupil sensing signals detected by the first and second biometric sensors 1031 and 1032 to the control module 1020, respectively.

The control module 1020 may be assembled to at least one side of the support frame 1002 together with at least one image display module 1010 or formed integrally with the support frame 1002. The control module 1020 supplies augmented reality content data to at least one image display module 1010 so that the at least one image display module 1010 displays an augmented reality content such as an augmented reality content image. At the same time, the control module 1020 may receive the sensing signals, the image data, and the pupil detection signals from the surrounding environment detection unit 1040 in real time.

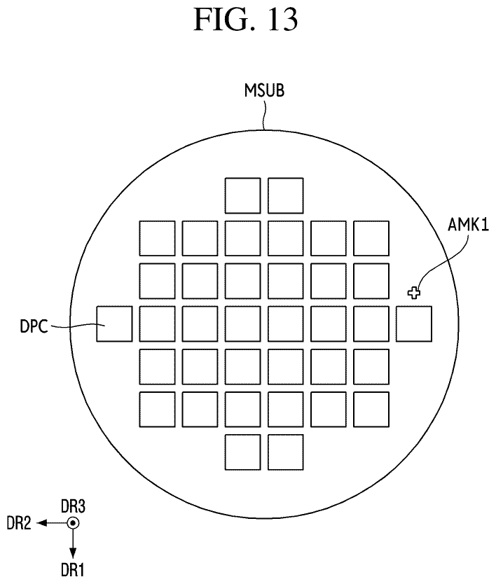

FIG. 13 is a plan view illustrating a mother semiconductor substrate including a display cell according to an embodiment.

Referring to FIG. 13 in addition to FIGS. 1 to 12, a mother semiconductor substrate MSUB may be configured as a semiconductor wafer. The mother semiconductor substrate MSUB may include a group IV material or a group III-V compound. In some embodiments, the mother semiconductor substrate MSUB may be configured as a single crystal wafer. For example, the mother semiconductor substrate MSUB may be a silicon substrate, a germanium substrate, or a silicon-germanium substrate.

However, the mother semiconductor substrate MSUB is not limited to the single crystal wafer, and may be various wafers such as an epi or epitaxial wafer, a polished wafer, an annealed wafer, and a silicon on insulator (SOI) wafer. The epitaxial wafer refers to a wafer in which a crystalline material is grown on a single crystal silicon substrate.

The mother semiconductor substrate MSUB may include a first alignment mark AMK1. The first alignment mark AMK1 will be described later.

The mother semiconductor substrate MSUB may include a plurality of display cells DPC. Each of the plurality of display cells DPC may be a preprocessing component that constitutes a portion of the display panel 100 described with reference to FIG. 1 and the like. For example, the mother semiconductor substrate MSUB may constitute the semiconductor substrate SSUB of the display panel 100, and the plurality of display cells DPC may constitute the semiconductor backplane SBP, the display element layer EML, and the encapsulation layer TFE of the display panel 100.

The plurality of display cells DPC may be formed using semiconductor equipment or formed by a semiconductor process, but are not limited thereto. The display panel 100 may be formed by forming the plurality of display cells DPC on the mother semiconductor substrate MSUB and then performing cell cutting in units of each display cell DPC in another embodiment.

Although not illustrated in FIG. 13, each of the plurality of display cells DPC may include a plurality of pixels PX, and each of the plurality of pixels PX may include a plurality of light emitting elements. The light emitting layer IL (see FIG. 7) or the light emitting layer 172 (see FIG. 8) included in the light emitting element may be formed through a deposition process. In general, in order to form the light emitting layer IL or the light emitting layer 172 in a high-resolution display device 10 through the deposition process, a more precise deposition mask may be required. Hereinafter, a deposition mask for forming the high-resolution display device 10 will be described.

FIG. 14 is a plan view illustrating a deposition mask according to an embodiment.

Referring to FIG. 14 in addition to FIGS. 1 to 13, a deposition mask 800 according to an embodiment may be a deposition mask used to manufacture an ultrahigh-resolution display. As an example, the deposition mask 800 may be a deposition mask used to manufacture a display included in a head mounted display device or an augmented reality content providing device.

In an embodiment, the deposition mask 800 may be used to perform a pixel deposition process on a silicon wafer. In general, a display included in an extended reality device may have a small screen rather than a size of a great area because a screen is positioned directly in front of user's eyes. In addition, such a display may require an ultrahigh resolution because the screen is positioned close to the user's eyes. As an example, a resolution required in the display included in the extended reality device may be approximately 1000 pixels per inch (PPI) or higher, and preferably, an ultrahigh resolution of 3000 PPI or higher. The deposition mask 800 according to an embodiment may be a mask used to manufacture such an ultrahigh-resolution display. In other words, the deposition mask 800 may be a fine silicon mask (FSM).

The deposition mask 800 may include a mask substrate 810 and a plurality of mask cells MSC.

The mask substrate 810 may be configured as a semiconductor wafer. The mask substrate 810 may include a group IV material or a group III-V compound. In some embodiments, the mask substrate 810 may be configured as a single crystal wafer. For example, the mask substrate 810 may be a silicon substrate, a germanium substrate, or a silicon-germanium substrate. However, the mask substrate 810 is not limited to the single crystal wafer, and may be various wafers such as an epi or epitaxial wafer, a polished wafer, an annealed wafer, and a silicon on insulator (SOI) wafer in another embodiment. The epitaxial wafer refers to a wafer in which a crystalline material is grown on a single crystal silicon substrate.

The mask substrate 810 is a substrate of the ultrahigh-resolution display, and may have the same size or shape as the mother semiconductor substrate MSUB.

The plurality of mask cells MSC may be disposed to correspond to the plurality of display cells DPC of the mother semiconductor substrate MSUB. For example, in a deposition process for manufacturing the display device 10, a plurality of mask cells MSC may overlap the plurality of display cells DPC of the mother semiconductor substrate MSUB, respectively.

In this case, in order to align the plurality of mask cells MSC so as to overlap the plurality of display cells DPC, the mother semiconductor substrate MSUB may include the first alignment mark AMK1, and the deposition mask 800 may include a second alignment mark AMK2. The first alignment mark AMK1 and the second alignment mark AMK2 may each include metal, but are not limited thereto.

The plurality of mask cells MSC may be formed using semiconductor equipment or formed by a semiconductor process, but are not limited thereto. The deposition mask 800 according to the present embodiment may include an ultrahigh-resolution pattern by forming the plurality of mask cells MSC on the mask substrate 810 configured as the semiconductor wafer using the semiconductor equipment or through the semiconductor process. The ultrahigh-resolution display may be manufactured using such an ultrahigh-resolution pattern.

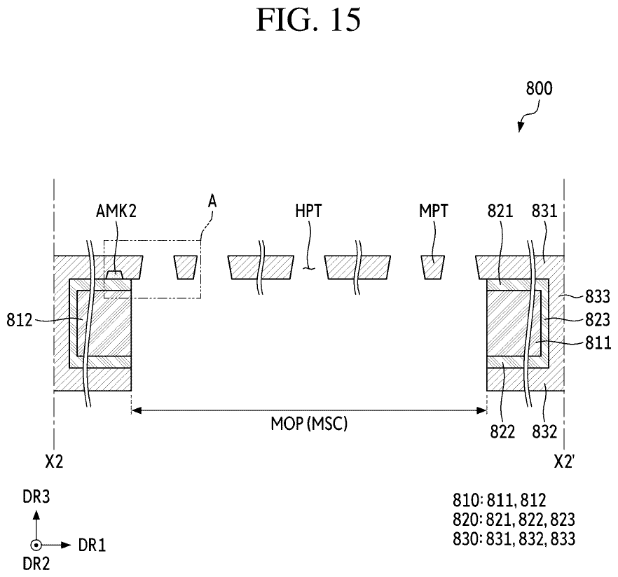

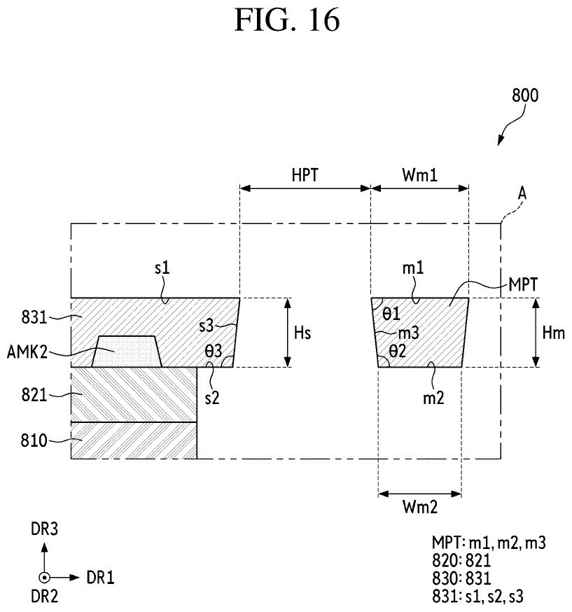

FIG. 15 is a cross-sectional view taken along line X2-X2′ of FIG. 14, and FIG. 16 is an enlarged cross-sectional view of area A of FIG. 15.

Referring to FIGS. 15 and 16 in addition to FIGS. 1 to 14, the deposition mask 800 may include a mask substrate 810, a first coating film 820, the second alignment mark AMK2, a second coating film 830, a hole pattern HPT, and a mask pattern MPT. An overlapping description of the mask substrate 810 is omitted.

The mask substrate 810 may be positioned to surround a mask opening MOP. In other words, the mask substrate 810 may not overlap the mask opening MOP in the third direction DR3. Here, the third direction DR3 is a thickness direction of the deposition mask 800 (or the mask substrate 810) and perpendicular to a major surface of the mask substrate 810. The major surface of the mask substrate 810 is parallel to a plane defined by the first direction DR1 and the second direction DR2.

In cross section, the mask substrate 810 may be divided into a first portion 811 and a second portion 812 by the mask opening MOP. In cross section, the first portion 811 and the second portion 812 may be spaced apart from each other with the mask opening MOP therebetween. However, this is an example in cross section, and in another embodiment, the first portion 811 and the second portion 812 may be formed integrally with each other in a plan view.

In some embodiment, a plurality of mask openings MOP may be configured to correspond to the mask cells MSC. For example, the plurality of mask openings MOP may be disposed in the plurality of multiple mask cells MSC, respectively. However, the present disclosure is not limited thereto, and one mask opening MOP may be formed over the entirety of the plurality of mask cells MSC in another embodiment.

The first coating film 820 may be disposed on the mask substrate 810. The first coating film 820 may be positioned to surround the mask opening MOP.

The first coating film 820 may be in contact with and cover an upper surface, a lower surface, and a side surface of the mask substrate 810. The first coating film 820 may include a first upper coating film 821 disposed on the upper surface of the mask substrate 810, a first lower coating film 822 disposed on the lower surface of the mask substrate 810, and a first side surface coating film 823 disposed on the side surface of the mask substrate 810. However, the present disclosure is not limited thereto, and the first coating film 820 may also include only the first upper coating film 821 in another embodiment.

The first coating film 820 may be an inorganic film including an inorganic material. For example, the first coating film 820 may include silicon oxide (SiOₓ).

The second alignment mark AMK2 may be disposed on the first coating film 820. However, the present disclosure is not limited thereto, and the second alignment mark AMK2 may also be disposed on the mask substrate 810 or disposed on the second coating film 830 in another embodiment. An overlapping description is omitted.

The second coating film 830 may be disposed on the second alignment mark AMK2 and the first coating film 820. The second coating film 830 may be positioned to surround the mask opening MOP.

The second coating film 830 may be an inorganic film including an inorganic material, and the first coating film 820 and the second coating film 830 may include different materials. As an example, the second coating film 830 may include silicon nitride (SiNₓ).

In some embodiments, the second coating film 830 may include low stress nitride (LSN). The second coating film 830 of the deposition mask 800 includes the low stress nitride, and accordingly, durability of the deposition mask 800 may be improved. As an example, the second coating film 830 of the deposition mask 800 includes the low stress nitride, and accordingly, a coating film detachment defect due to thin film stress may be solved.

The second coating film 830 may be positioned on the mask substrate 810, and may be in contact with and cover the first coating film 820. The second coating film 830 may include a second upper coating film 831 disposed on the upper surface of the mask substrate 810, a second lower coating film 832 disposed on the lower surface of the mask substrate 810, and a second side surface coating film 833 disposed on the side surface of the mask substrate 810. Specifically, the second upper coating film 831 may be in contact with and cover the first upper coating film 821, the second lower coating film 832 may be in contact with and cover the first lower coating film 822, and the second side surface coating film 833 may be in contact with and cover the first side surface coating film 823. However, the present disclosure is not limited thereto, and the second coating film 830 may also include only the second upper coating film 831 in another embodiment.

The deposition mask 800 according to an embodiment may include a plurality of mask patterns MPT and a plurality of hole patterns HPT in a portion that overlaps the mask opening MOP. The plurality of mask patterns MPT and the plurality of hole patterns HPT may not overlap the mask substrate 810 in the third direction DR3.

The plurality of mask patterns MPT and the plurality of hole patterns HPT may be alternately disposed. In other words, the respective mask patterns MPT may be spaced apart from each other with the hole pattern HPT interposed therebetween, and some of the mask patterns MPT may be spaced apart from the second coating film 830 with the hole pattern HPT interposed therebetween.

The plurality of mask patterns MPT may be spaced apart from each other in the first direction DR1 or the second direction DR2 in cross section, but may be one pattern connected to each other in a plan view. In other words, the mask pattern MPT may refer to all of a plurality of patterns positioned on the mask substrate 810 as one configuration or may refer to each of the plurality of patterns. That is, the plurality of mask patterns MPT may be used interchangeably to refer to the entirety of a group of the plurality of patterns as one configuration or refer to each of the plurality of patterns.

The mask pattern MPT may include the same material as the second coating film 830. In a manufacturing process of the deposition mask 800, the mask pattern MPT and the second coating film 830 are formed integrally with each other, and portions of the second coating film 830 are then removed by a subsequent etching process, and accordingly, the mask pattern MPT and the second coating film 830 formed integrally with each other may be divided into forms of the mask pattern MPT and the second coating film 830 in FIG. 15.

Accordingly, the mask pattern MPT may include the same material as the second coating film 830. Specifically, the mask pattern MPT may be an inorganic film including an inorganic material, and may include, for example, silicon nitride (SiNₓ).

The hole pattern HPT according to an embodiment may be in communication with the mask opening MOP. Accordingly, the mask opening MOP and the hole pattern HPT may provide a passage through which a deposition material for forming the pixel PX of the display panel 100 included in the display device 10 may move.

In an embodiment, the mask pattern MPT may include a first surface m1, a second surface m2, and a first side surface m3. The first surface m1 may be one surface facing one side in the third direction DR3, the second surface m2 may be one surface opposing the first surface m1, and the first side surface m3 may be one surface connecting the first surface m1 and the second surface m2 to each other. The first surface m1 may be one surface positioned in a direction opposite to a direction in which the mask substrate 810 is positioned. In other words, the first surface m1 may be a top surface, and the second surface m2 may be a bottom surface of the mask pattern MPT.

In some embodiments, a width Wm2 of the second surface m2 of the mask pattern MPT may be smaller than a width Wm1 of the first surface m1 of the mask pattern MPT. In addition, a first inclination angle θ1 formed by the first surface m1 and the first side surface m3 of the mask pattern MPT may be smaller than a second inclination angle θ2 formed by the second surface m2 and the first side surface m3 of the mask pattern MPT. In an embodiment, the first inclination angle θ1 may be an acute angle, and the second inclination angle θ2 may be an obtuse angle. As an example, the second inclination angle θ2 may have a value of 90° or more to 135° or less.

In other words, the mask pattern MPT included in the deposition mask 800 according to an embodiment may have a reverse tapered shape in a cross-sectional view.

The deposition mask 800 according to an embodiment includes the mask pattern MPT having the reverse tapered shape, and accordingly, deposition efficiency of a material to be deposited may be improved and a shadow defect of the display device 10 may be solved. A detailed description will be provided later.

In some embodiments, a height Hm of the mask pattern MPT may have a range of 0.1 μm or more to 3.0 μm or less.

In an embodiment, the second upper coating film 831 included in the second coating film 830 may include a first surface s1, a second surface s2 opposing the first surface s1, and a second side surface s3 connecting the first surface s1 and the second surface s2 to each other. The first surface s1 of the second upper coating film 831 may be one surface facing one side in the third direction DR3, the second surface s2 of the second upper coating film 831 may be one surface facing the first upper coating film 821 included in the first coating film 820, and the second side surface s3 of the second upper coating film 831 may be one surface facing the hole pattern HPT.

The first side surface m3 of the mask pattern MPT and the second side surface s3 of the second upper coating film 831 may face each other with the hole pattern HPT interposed therebetween.

In some embodiments, a third inclination angle θ3 formed by the second surface s2 and the second side surface s3 of the second upper coating film 831 may be an obtuse angle. As an example, the third inclination angle θ3 may have a value of 90° or more to 135° or less.

The second coating film 830 and the mask pattern MPT may have the same height. As an example, a height Hs of the second coating film 830 may have a range of 0.1 μm or more to 3.0 μm or less.

In some embodiments, the second side surface s3 of the second upper coating film 831 may protrude more than the first upper coating film 821 and the mask substrate 810 toward the hole pattern HPT in the first direction DR1, but is not limited thereto.

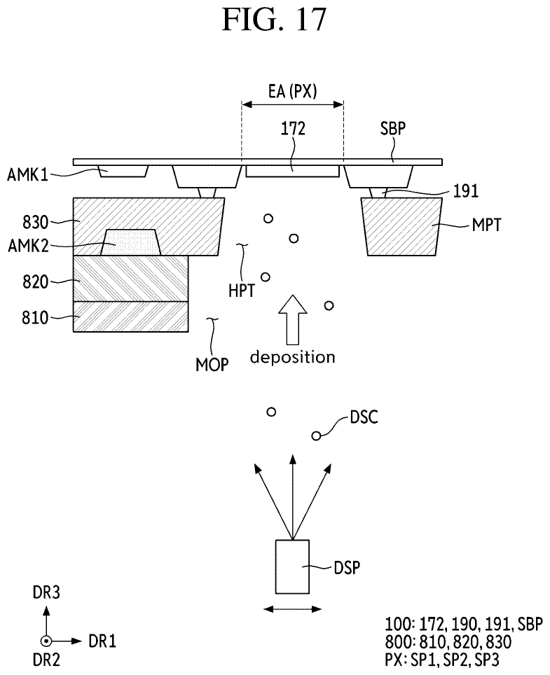

FIG. 17 is a cross-sectional view illustrating a process of manufacturing the display panel using the deposition mask according to an embodiment.

Referring to FIG. 17 in addition to FIGS. 1 to 16, the deposition mask 800 according to an embodiment may be used to form a light emitting layer (e.g., 172) overlapping each pixel PX of the display panel 100. The display panel 100 of FIG. 8 has been illustrated by way of example in FIG. 17, but the deposition mask 800 may also be used to form the light emitting layer IL of the display panel 100 described with reference to FIG. 7.

In the present process, the display panel 100 may be positioned on the deposition mask 800 in the third direction DR3, and the deposition mask 800 may be seated on the spacer 191 of the display panel 100.

In the present process, a portion where the light emitting layer 172 of the display panel 100 is deposited may be positioned toward a direction in which the deposition mask 800 is positioned. In this case, the deposition mask 800 and the display panel 100 may be aligned with each other using the first alignment mark AMK1 and the second alignment mark AMK2.

In the present process, materials (deposition sources DSC) for forming the light emitting layer 172 may be sprayed from a deposition source supply unit DSP. The above-described deposition sources DSC may include different materials depending on colors emitted by the first to third sub-pixels SP1, SP2, and SP3.

Subsequently, the deposition sources DSC sprayed from the deposition source supply unit DSP may pass through the mask opening MOP and the hole pattern HPT of the deposition mask 800 and be then deposited on the semiconductor backplane SBP of the display panel 100.

As an example, when some of the deposition sources DSC sprayed from the deposition source supply unit DSP do not pass through the mask opening MOP and the hole pattern HPT and are deposited on the mask pattern MPT in the present process, a ratio of the deposition sources DSC seated on the display panel 100 may be reduced. As an example, when the ratio of the deposition sources DSC seated on the display panel 100 is 90% or less of a target thickness, a shadow defect may occur in the display panel 100. The above-described shadow defect may occur because the deposition sources DSC are formed at an uneven thickness in a portion overlapping the emission area EA of the display panel 100.

The deposition mask 800 according to an embodiment may solve the above-described shadow defect by including the mask pattern MPT having the reverse tapered shape in a cross-sectional view. As described above, in the mask pattern MPT according to an embodiment, the width Wm2 of the second surface m2 may be smaller than the width Wm1 of the first surface m1, the second inclination angle θ2 may have the value of 90° or more to 135° or less, and the height Hm of the mask pattern MPT may have the range of 0.1 μm or more to 3.0 μm or less. For this reason, the deposition mask 800 according to an embodiment may reduce the ratio of the deposition sources DSC deposited on the mask pattern MPT, and may help the deposition sources DSC to be seated on the display panel 100 at a target thickness.

In addition, in the deposition mask 800 according to an embodiment, the mask substrate 810 includes a protrusion portion, and accordingly, the making pattern MPT having the reverse tapered shape may be manufactured without a separate process. For this reason, the deposition mask 800 may have manufacturing easiness. Detailed contents will be described later.

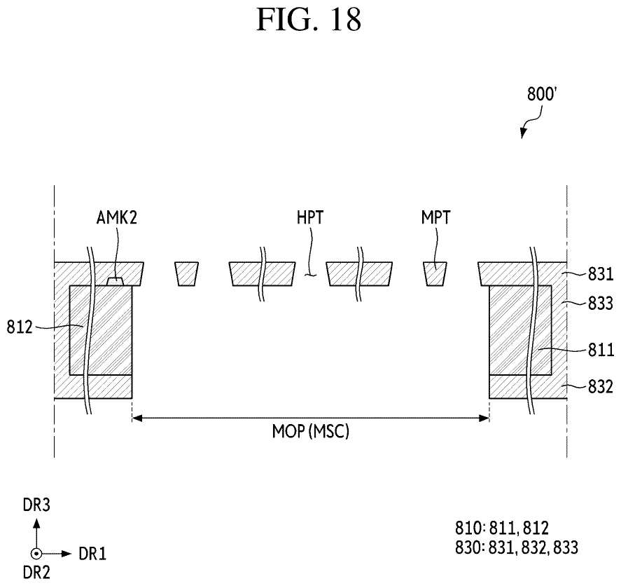

FIG. 18 is a cross-sectional view illustrating a deposition mask according to another embodiment.

Referring to FIG. 18, a deposition mask 800′ may include a mask substrate 810, a second alignment mark AMK2, a second coating film 830, a hole pattern HPT, and a mask pattern MPT. In other words, the deposition mask 800′ may have a different structure from the deposition mask 800 described above in that it does not include the first coating film 820 included in the deposition mask 800 described above. Hereinafter, the same components as those of the above-described embodiment will be denoted by the same reference numerals, and an overlapping description thereof will be omitted or simplified and contents different from those described above will be mainly described.

The second alignment mark AMK2 may be disposed on the mask substrate 810. However, the present disclosure is not limited thereto, and the second alignment mark AMK2 may also be disposed on the second coating film 830 in another embodiment.

The second coating film 830 may be disposed on the second alignment mark AMK2 and the mask substrate 810. The second coating film 830 may be in contact with and cover an upper surface, a lower surface, and a side surface of the mask substrate 810. For example, the second coating film 830 may include a second upper coating film 831 disposed in contact with the upper surface of the mask substrate 810, a second lower coating film 832 disposed in contact with the lower surface of the mask substrate 810, and a second side surface coating film 833 disposed in contact with the side surface of the mask substrate 810. However, the present disclosure is not limited thereto, and according to another embodiment, the second coating film 830 may also include only the second upper coating film 831.

The second coating film 830 may be an inorganic film including an inorganic material. For example, the second coating film 830 may include silicon nitride (SiNₓ).

In cross section, the mask substrate 810 of the deposition mask 800′ may be divided into a first portion 811 and a second portion 812 by a mask opening MOP, and may include a plurality of mask patterns MPT and a plurality of hole patterns HPT positioned in a portion overlapping the mask opening MOP. The plurality of mask patterns MPT included in the deposition mask 800′ may each have a reverse tapered shape, and may have the same features as the plurality of mask patterns MPT included in the deposition mask 800. A description of overlapping contents is omitted.

Hereinafter, a method for manufacturing the mask pattern MPT of the deposition mask 800 in the reverse tapered shape will be described.

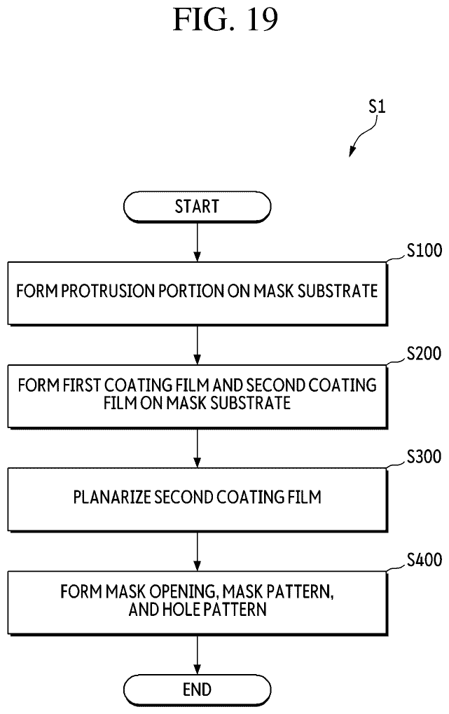

FIG. 19 is a flowchart illustrating a method for manufacturing the deposition mask according to an embodiment.

Referring to FIG. 19, a method (S1) for manufacturing the deposition mask according to an embodiment may include forming a protrusion portion on a mask substrate (S100), forming a first coating film and a second coating film on the mask substrate (S200), planarizing the second coating film (S300), and forming a mask opening, a mask pattern, and a hole pattern (S400).

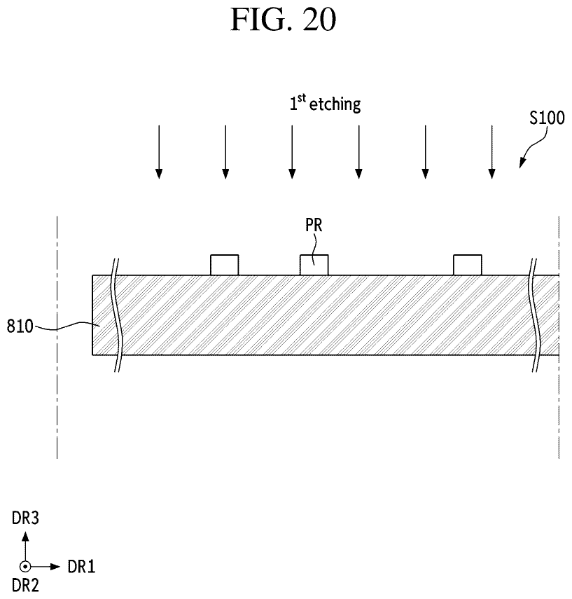

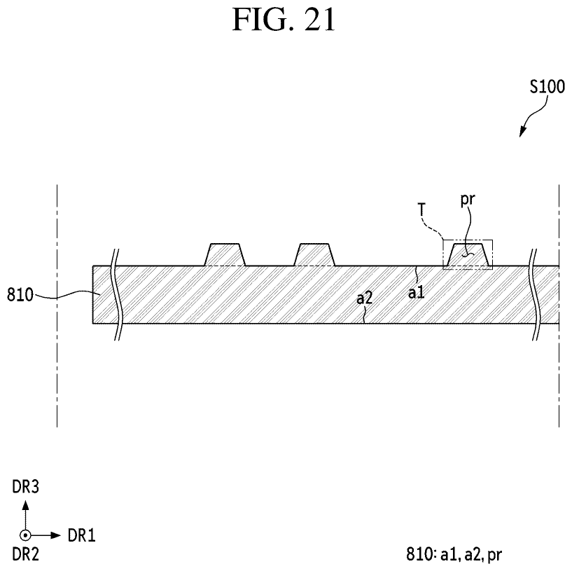

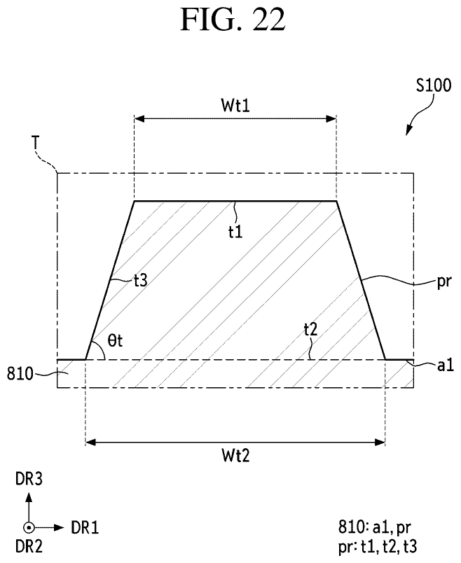

FIGS. 20 and 21 are cross-sectional views illustrating S100 of FIG. 19, and FIG. 22 is an enlarged cross-sectional view of area T of FIG. 21.

First, the forming of the protrusion portion on the mask substrate (S100) is described.

Referring to FIGS. 20 to 22, a plurality of photoresists PR are formed on the mask substrate 810. The mask substrate 810 may be configured as a semiconductor wafer, as described above. An overlapping description is omitted.

In the present process, the plurality of photoresists PR may be disposed to be spaced apart from each other. Thereafter, a first etching process (1^{st} etching) is performed using the plurality of photoresists PR as a mask. As an example, any one of a wet etching process or a dry etching process may be performed as the first etching process (1^{st} etching).

In the present process, portions of the mask substrate 810 that do not overlap the plurality of photoresists PR may be removed, and accordingly, the mask substrate 810 may have a protrusion portion pr protruding more than an upper surface a1 toward one side in the third direction DR3. A plurality of protrusion portions pr may be formed, and may be spaced apart from each other in the first direction DR1.

In an embodiment, the protrusion portion pr may have a first surface t1 protruding more than the upper surface a1 of the mask substrate 810 toward one side in the third direction DR3, a second surface t2 opposing the first surface t1, extending to the upper surface a1 of the mask substrate 810, and virtual, and a first side surface t3 connecting the first surface t1 and the second surface t2 to each other or connecting the first surface t1 and the upper surface a1 of the mask substrate 810 to each other.

In the present process, the protrusion portion pr may have a normal tapered shape or a trapezoidal shape in a cross-sectional view. In other words, an inclination angle θt formed by the second surface t2 of the protrusion portion pr and the first side surface t3 of the protrusion portion pr may have a range of 45° or more to 90° or less, and a width Wt2 of the second surface t2 of the protrusion portion pr may be greater than a width Wt1 of the first surface t1 of the protrusion portion pr.

FIG. 22 is a cross-sectional view illustrating S200 of FIG. 19.

Second, the forming of the first coating film and the second coating film on the mask substrate (S200) is described.

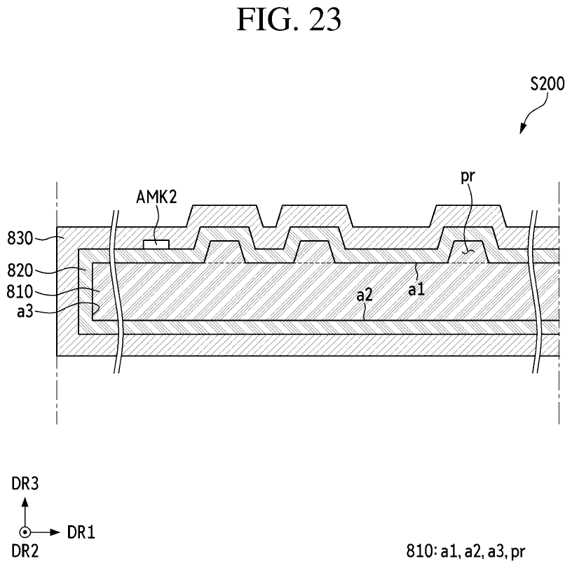

Referring to FIG. 23, the first coating film 820 is formed on the mask substrate 810. The first coating film 820 may cover a step formed by the upper surface a1 of the mask substrate 810 and the protrusion portion pr at a uniform thickness. The first coating film 820 may be in contact with and cover the upper surface a1, a lower surface a2, and a side surface a3 of the mask substrate 810. Accordingly, the first coating film 820 may have a step in a portion overlapping the protrusion portion pr.

The first coating film 820 may be an inorganic film including an inorganic material, as described above. For example, the first coating film 820 may include silicon oxide (SiOₓ).

Subsequently, a second alignment mark AMK2 is formed on the first coating film 820. As an example, the second alignment mark AMK2 may be formed by patterning an alignment mark material layer through a photolithography process. The alignment mark material layer may include metal, but is not limited thereto.

Next, the second coating film 830 is formed on the first coating film 820 and the second alignment mark AMK2. The second coating film 830 may cover a step formed by the upper surface a1 of the mask substrate 810 and the protrusion portion pr at a uniform thickness. Accordingly, the second coating film 830 may have a step in a portion overlapping the protrusion portion pr. The second coating film 830 may cover the upper surface a1, the lower surface a2, and the side surface a3 of the mask substrate 810.

The second coating film 830 may be an inorganic film including an inorganic material, as described above. For example, the second coating film 830 may include silicon nitride (SiNₓ).

In the present process, the first coating film 820 and the second coating film 830 may be formed by a low pressure chemical vapor deposition (LPCVD) process, but are not limited thereto.

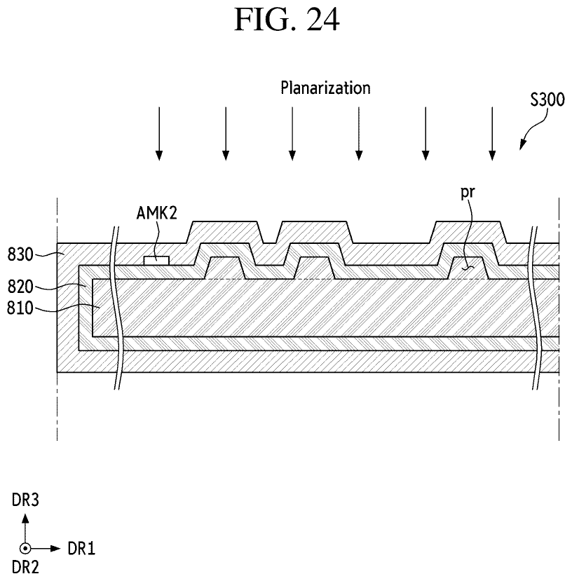

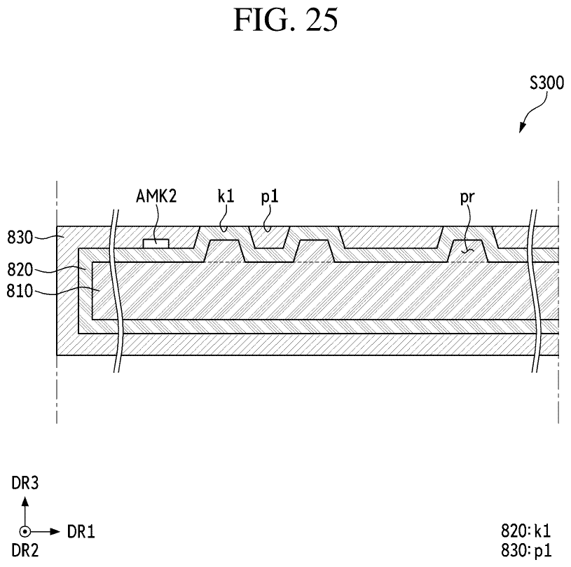

FIGS. 24 and 25 are cross-sectional views illustrating S300 of FIG. 19.

Third, the planarizing of the second coating film (S300) is described.

Referring to FIG. 24 and FIG. 25, the second coating film is planarized by removing a portion of the second coating film 830 overlapping the protrusion portion pr of the mask substrate 810.

In the present process, the second coating film 830 overlapping the protrusion portion pr may be removed up to a point positioned on the same line as an upper surface k1 of the first coating film 820. For this reason, in the present process, an upper surface p1 of the second coating film 830 may be positioned on the same line as the upper surface k1 of the first coating film 820. Each of the upper surface p1 of the second coating film 830 and the upper surface k1 of the first coating film 820 may be one surface facing one side in the third direction DR3. In other words, each of the upper surface p1 of the second coating film 830 and the upper surface k1 of the first coating film 820 may be one surface positioned in a direction opposite to a direction in which the mask substrate 810 is positioned. The meaning of the phrase “on the same line” described above may include a process error within 1 μm.

In the present process, a process of planarizing the second coating film 830 may be performed through any one of a chemical mechanical polishing (CMP) process or a photolithography process.

As an example, the CMP process is a chemical mechanical polishing process, and may planarize the second coating film 830 by generating a chemical reaction and at the same time, applying physical force to polish the second coating film 830, and the photolithography process may planarize the second coating film 830 by performing an etching process using a photoresist PR.

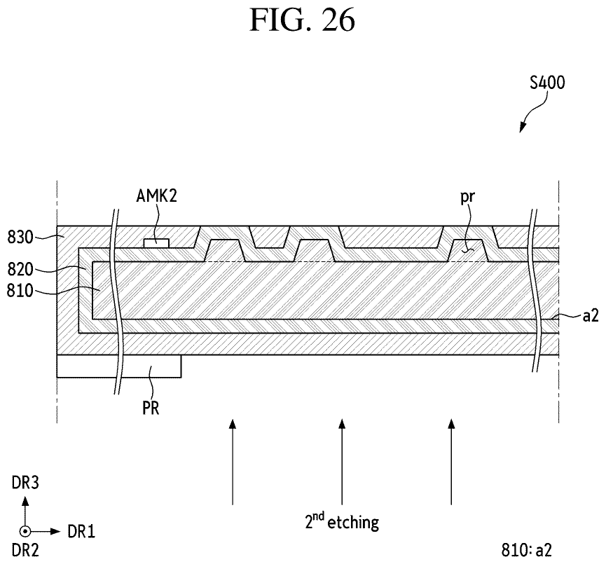

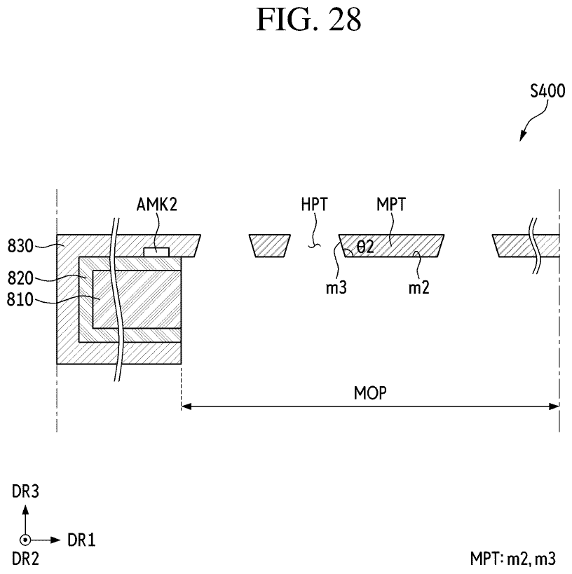

FIGS. 26 to 28 are cross-sectional views illustrating S400 of FIG. 19.

Fourth, the forming of the mask opening, the mask pattern, and the hole pattern (S400) is described.

Referring to FIGS. 26 to 28, a photoresist PR is formed on the lower surface a2 of the mask substrate 810, and a second etching process (2^{nd} etching) is then performed using the photoresist PR as a mask. As an example, in the second etching process (2^{nd} etching), dry etching processes and wet etching processes may be alternately performed.

In the present process, the second etching process (2^{nd} etching) may be performed in a direction toward the lower surface a2 of the mask substrate 810. In other words, the second etching process (2^{nd} etching) may be performed in a rear surface direction of the mask substrate 810.

In the present process, the first coating film 820 and the second coating film 830 that are positioned on the lower surface a2 of the mask substrate 810 and do not overlap the photoresist PR may be first removed, and the mask substrate 810 that does not overlap the photoresist PR may be subsequently removed. Consequently, a mask opening MOP may be formed.

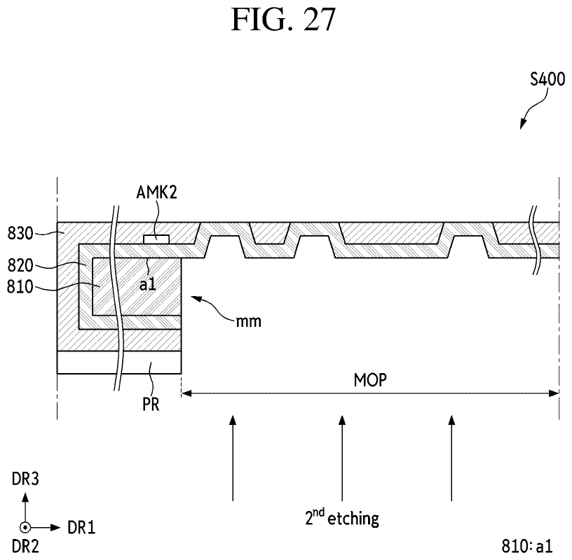

It has been illustrated in FIG. 27 that an inner side surface mm of the mask opening MOP is a vertical surface, but the present disclosure is not limited thereto. For another example, the inner side surface mm of the mask opening MOP may also be an inclined surface or a curved surface by the etching process.

Next, the first coating film 820 that is positioned on the upper surface a1 of the mask substrate 810 and does not overlap the photoresist PR may be removed by the second etching process (2^{nd} etching) performed in the rear surface direction of the mask substrate 810. In the present process, portions of the second coating film 830 remaining in a portion overlapping the mask opening MOP may be formed as a mask pattern MPT and a hole pattern HPT.

In the present process, the mask pattern MPT may have a reverse tapered shape as described above in FIG. 16. For example, a second inclination angle θ2 formed by a second surface m2 and a first side surface m3 of the mask pattern MPT may be an obtuse angle, and may have a value of 90° or more to 135° or less.

In an embodiment, the mask substrate 810 of the deposition mask 800 includes the protrusion portion pr having the normal tapered shape, and thus, the mask pattern MPT having the reverse tapered shape may be formed without a separate additional process. Accordingly, the deposition mask 800 according to an embodiment may have manufacturing easiness.

In addition, the deposition mask 800 according to an embodiment includes the mask pattern MPT having the reverse tapered shape, and accordingly, deposition efficiency of a material deposited on the display panel 100 illustrated in FIGS. 1 to 8 may be effectively improved. For this reason, a shadow defect of the display panel 100 may be solved.

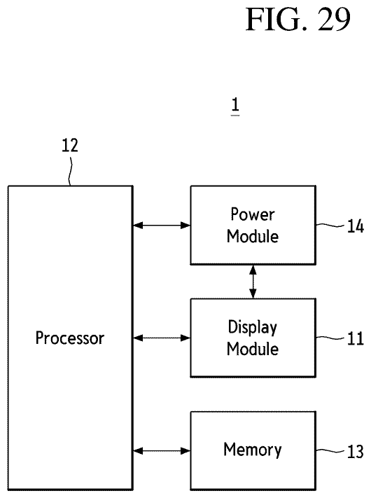

FIG. 29 is a block diagram of an electronic device according to one embodiment of the present disclosure.

Referring to FIG. 29, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

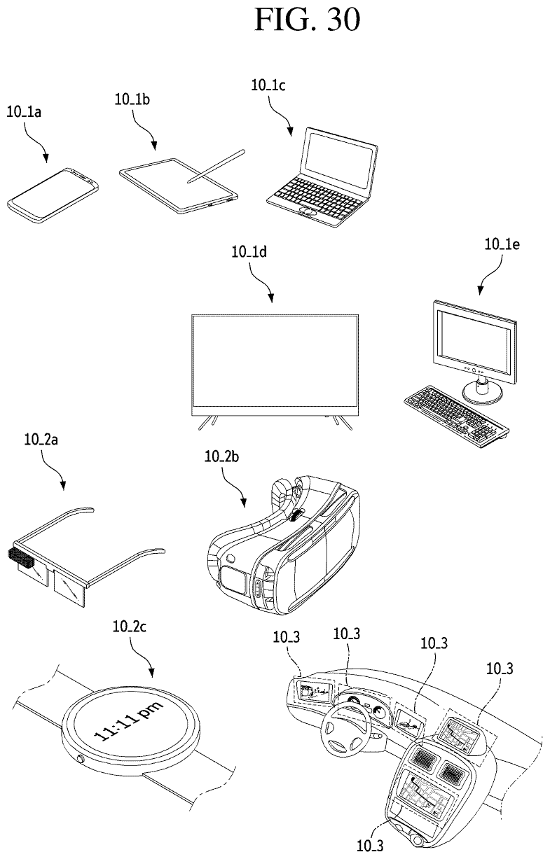

FIG. 30 is a schematic diagram of an electronic device according to various embodiments of the present disclosure.

Referring to FIG. 30, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

Embodiments of the disclosure should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition mask comprising:
a mask substrate positioned to surround a mask opening;
a coating film disposed on the mask substrate and including an inorganic material; and
a mask pattern positioned in a portion overlapping the mask opening and spaced apart from the coating film with a hole pattern interposed therebetween,
wherein the mask pattern includes:
a top surface;
a bottom surface opposing the top surface and facing the mask opening; and
a side surface connecting the top surface and the bottom surface to each other and facing the hole pattern, and
wherein a first inclination angle formed by the top surface and the side surface is smaller than a second inclination angle formed by the bottom surface and the side surface.

2. The deposition mask of claim 1, wherein the first inclination angle is an acute angle, and the second inclination angle is an obtuse angle.

3. The deposition mask of claim 2, wherein the second inclination angle is greater than 90° and less than or equal to 135°.

4. The deposition mask of claim 3, wherein a width of the top surface of the mask pattern is greater than a width of the bottom surface of the mask pattern.

5. The deposition mask of claim 1, wherein the coating film includes:
a first coating film positioned in contact with the mask substrate; and
a second coating film positioned on the first coating film,
wherein the mask pattern is arranged in line with an upper portion of the second coating film, and
the mask pattern is spaced apart from the second coating film with the hole pattern interposed therebetween.

6. The deposition mask of claim 5, wherein the mask pattern and the second coating film include a same material, and
a height of the mask pattern and a height of the second coating film are the same as each other.

7. The deposition mask of claim 6, wherein the height of the mask pattern is 0.1 micrometers (μm)to 3.0 μm.

8. The deposition mask of claim 5, wherein the first coating film and the second coating film include different inorganic materials from each other.

9. The deposition mask of claim 8, wherein the first coating film includes silicon oxide, and
the second coating film includes silicon nitride.

10. The deposition mask of claim 1, wherein in a direction perpendicular to a major surface of the mask substrate, the coating film overlaps the mask substrate, and the mask pattern does not overlap the mask substrate.

11. A method for manufacturing a deposition mask, comprising:
forming a plurality of protrusion portions on a mask substrate configured as a semiconductor wafer;
forming a first coating film and a second coating film on the mask substrate;
planarizing the second coating film by removing a portion of the second coating film; and
forming a mask opening, a mask pattern, and a hole pattern by removing portions of the mask substrate, the first coating film, and the second coating film,
wherein the protrusion portion protrudes more than an upper surface of the mask substrate in a direction perpendicular to a major surface of the mask substrate.

12. The method for manufacturing a deposition mask of claim 11, wherein in the forming of the plurality of protrusion portions, each of the plurality of protrusion portions includes:
a top surface protruding more than the upper surface of the mask substrate;
a bottom surface opposing the top surface and positioned on a same plane as the upper surface of the mask substrate; and
a side surface connecting the top surface and the bottom surface to each other, and
a width of the top surface is smaller than a width of the bottom surface.

13. The method for manufacturing a deposition mask of claim 12, wherein in the forming of the plurality of protrusion portions, an inclination angle formed by the bottom surface and the side surface of each of the plurality of protrusion portions is 45° to 90°.

14. The method for manufacturing a deposition mask of claim 11, wherein in the forming of the plurality of protrusion portions, each of the plurality of protrusion portions has a trapezoidal shape in a cross-sectional view.

15. The method for manufacturing a deposition mask of claim 11, wherein in the forming of the first coating film and the second coating film,
the first coating film and the second coating film are formed by a low pressure chemical vapor deposition (LPCVD) process, and
the second coating film includes low stress nitride.

16. The method for manufacturing a deposition mask of claim 15, wherein in the forming of the first coating film and the second coating film, the first coating film and the second coating film each cover the mask substrate at a uniform thickness along a shape of the protrusion portion.

17. The method for manufacturing a deposition mask of claim 16, wherein in the planarizing of the second coating film, a portion of the second coating film overlapping the protrusion portion is removed by at least one of a chemical mechanical polishing (CMP) process or a photolithography process.

18. The method for manufacturing a deposition mask of claim 11, wherein in the forming of the mask opening, the mask pattern, and the hole pattern, the mask opening, the hole pattern, and the mask pattern are formed by removing the portions of the mask substrate, the first coating film, and the second coating film by an etching process performed in a lower surface direction of the mask substrate.

19. The method for manufacturing a deposition mask of claim 18, wherein in the forming of the mask opening, the mask pattern, and the hole pattern,
the mask pattern is originally a portion of the second coating film, and is then separated apart from the second coating film with the hole pattern interposed therebetween by the etching process, and
the mask pattern has a reverse tapered shape in a cross-sectional view.
, wherein in the forming of the mask opening, the mask pattern, and the hole pattern,
the mask substrate is positioned to surround the mask opening, and
the mask opening is in communication with the hole pattern.

20. An electronic device comprising:
a display device formed using a deposition mask;
the deposition mask comprising:
a mask substrate positioned to surround a mask opening;
a coating film disposed on the mask substrate and including an inorganic material; and
a mask pattern positioned in a portion overlapping the mask opening and spaced apart from the coating film with a hole pattern interposed therebetween,
wherein the mask pattern includes:
a top surface;
a bottom surface opposing the top surface and facing the mask opening; and
a side surface connecting the top surface and the bottom surface to each other and facing the hole pattern, and
wherein a first inclination angle formed by the top surface and the side surface is smaller than a second inclination angle formed by the bottom surface and the side surface.
